(19) United States
(12) Patent Application Publication
(10) Pub. No.: US 2025/0349674 A1
(43) Pub. Date: Nov. 13, 2025

(54) SEMICONDUCTOR DIE PACKAGES AND METHODS OF FORMATION

(71) Applicant: Taiwan Semiconductor Manufacturing Company, Ltd., Hsinchu (TW)

(72) Inventors: Wei Hsiang CHAN, Hsinchu (TW); Chi-Feng LIN, Hsinchu City (TW); Jo-Lin LAN, Kaohsiung City (TW); Ming-Yuan GAO, Hsinchu (TW); Chun Hsiang YANG, New Taipei City (TW); Woei-Shyang LIN, New Taipei City (TW); Kuan-Ju CHEN, Kaohsiung City (TW); I-Hsin TSENG, Hsinchu County (TW); Jung-Hsuan SU, Taipei City (TW)

(21) Appl. No.: 18/657,232

(22) Filed: May 7, 2024

(51) Int. Cl. H01L 23/48; H01L 21/768; H01L 23/00; H01L 23/528; H01L 25/065

(52) U.S. Cl. CPC H01L 23/481; H01L 21/76843; H01L 23/5283; H01L 24/08; H01L 25/0657; H01L 24/80; H01L 2224/08145; H01L 2224/80895; H01L 2224/80896; H01L 2924/1436; H01L 2924/1437; H01L 2924/14511

(57) ABSTRACT

An elongated conductive structure is included through a device layer of a semiconductor die included in a semiconductor die package. The elongated conductive structure connects to metallization layers in interconnect layers on opposing sides of the device layer. A blocking material is used to inhibit growth of barrier layers on the elongated conductive structure during formation of the barrier layers for the metallization layers. This enables the metallization layers to land directly on the elongated conductive structure as opposed to the barrier layers being between the elongated conductive structure and the metallization layers. In this way, metal-to-metal connections may be achieved between the conductive structure and the metallization layers, which enables a low contact resistance to be achieved between the conductive structure and the metallization layers while enabling barrier layers to be formed to provide diffusion protection for the metallization layers.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor die package described herein.

FIGS. 2A-2E are diagrams of an example implementation of forming a semiconductor die described herein.

FIGS. 3A-3M are diagrams of an example implementation of forming a semiconductor die described herein.

FIGS. 4A-4J are diagrams of an example implementation of forming a semiconductor die package described herein.

FIGS. 5A and 5B are diagrams of an example semiconductor die package described herein.

FIG. 6 is a diagram of an example semiconductor die package described herein.

FIG. 7 is a flowchart of an example process associated with forming a semiconductor die described herein.

FIG. 8 is a flowchart of an example process associated with forming a semiconductor die package described herein.

FIGS. 9A-9E are diagrams of an example implementation of forming a semiconductor die package described herein.

FIG. 10 is a diagram of an example semiconductor die package described herein.

FIG. 11 is a flowchart of an example process associated with forming a semiconductor die described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die in a semiconductor die package may be connected to interconnect layers on both sides of the semiconductor die. For example, a first interconnect layer may be included on a first side (e.g., a front side) of the semiconductor die, and a second interconnect layer may be included on a second side (e.g., a back side) of the semiconductor die opposing the first die. In some cases, the first interconnect layer may be used for routing signals throughout the semiconductor die, and the second interconnect layer may be used for providing power to the integrated circuit devices of the semiconductor die. Additionally and/or alternatively, one of the first or second interconnect layers may be bonded to another semiconductor die and may be used for inter-die communication, and the other interconnect layer may be connected to the connector of the semiconductor die package for making external connections.

To enable signals and/or power to be routed between the first and second interconnect layers, one or more elongated conductive structures may be included through a device layer (e.g., a semiconductor layer) in which the integrated circuit devices are included. The elongated conductive structure(s) (sometimes referred to as through silicon vias (TSVs)) connect with one or more metallization layers in the first and second interconnect layers, and may be formed of electrically conductive metals such as copper (Cu) to achieve a low electrical resistance between the metallization layers in the first and second interconnect layers through the elongated conductive structure(s). However, the electrically conductive metal(s) of the elongated conductive structure(s) (and from the metallization layers in the first and second interconnect layers) may suffer from diffusion into surrounding dielectric layers of the first and second interconnect layers and/or into the device layer of the semiconductor die. The diffusion of electrically conductive metal(s) may result in increased electrical resistance for the elongated conductive structure(s) and/or for the metallization layers in the first and second interconnect layers. Moreover, the diffusion of electrically conductive metal(s) may result in increased current leakage in the semiconductor die.

Barrier layers may be included between the elongated conductive structure(s) and the surrounding dielectric layers and device layer, and between the metallization layers in the first and second interconnect layers, to reduce and/or minimize diffusion of electrically conductive metal(s). However, the barrier layers have a higher resistivity than the electrically conductive metal(s) of the elongated conductive structure(s) and of the metallization layers in the first and second interconnect layers. Thus, if the barrier layers are included between the elongated conductive structure(s) and the metallization layers in the first and second interconnect layers, the barrier layers may also result in increased electrical resistance for the elongated conductive structure(s) and the metallization layers in the first and second interconnect layers.

In some implementations described herein, an elongated conductive structure is included through a device layer of a semiconductor die included in a semiconductor die package. The elongated conductive structure connects to metallization layers in the interconnect layers on opposing sides of the device layer. To achieve a low contact resistance between the elongated conductive structure and the metallization layers, blocking material is used to inhibit growth of barrier layers on the elongated conductive structure during formation of the barrier layers for the metallization layers. This enables the metallization layers to land directly on the elongated conductive structure as opposed to the barrier layers being between the elongated conductive structure and the metallization layers. In this way, metal-to-metal connections may be achieved between the conductive structure and the metallization layers, which enables a low contact resistance to be achieved between the conductive structure and the metallization layers while enabling barrier layers to be formed to provide diffusion protection for the metallization layers. This enables low power consumption and increased signal propagation speeds to be achieved in the semiconductor die package.

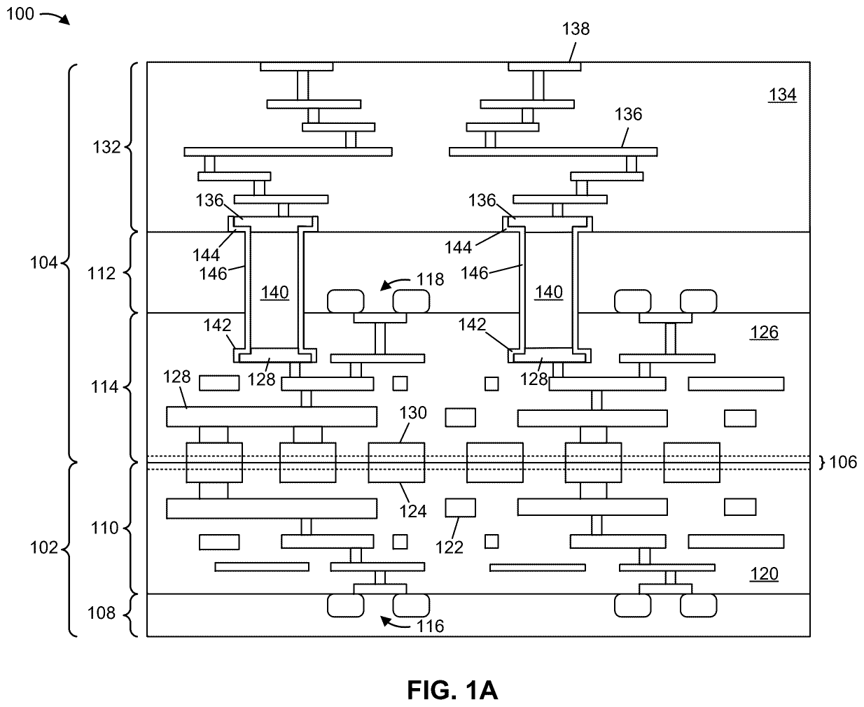

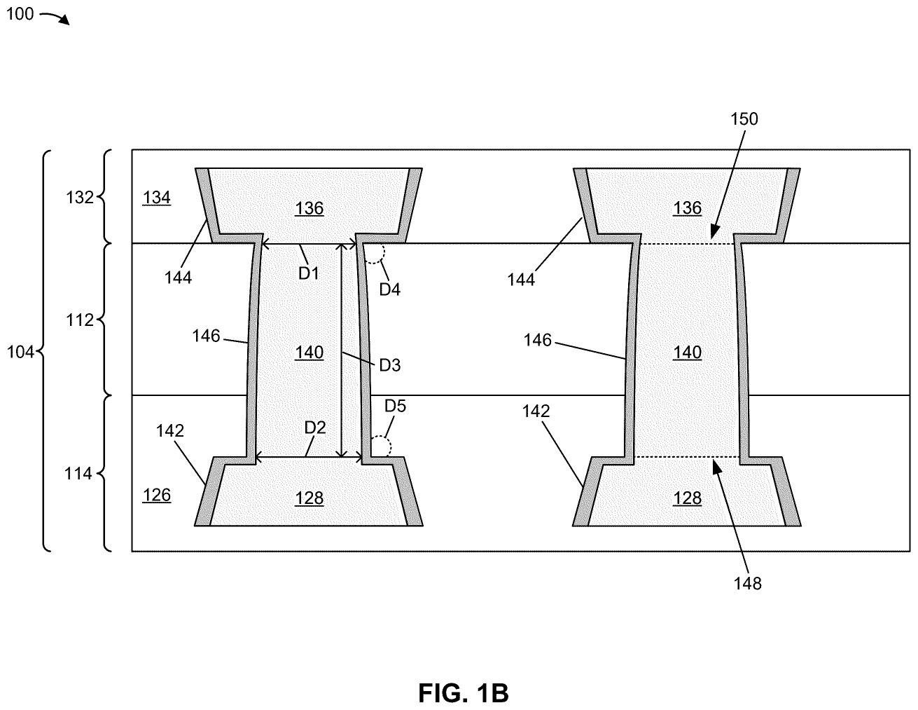

FIGS. 1A and 1B are diagrams of an example semiconductor die package 100 described herein. FIG. 1A illustrates a cross-section view of the semiconductor die package 100. As shown in FIG. 1A, the semiconductor die package 100 includes a semiconductor die 102 and a semiconductor die 104 bonded at a bonding interface 106 such that the semiconductor dies 102 and 104 are stacked and vertically arranged in the semiconductor die package 100. The bond between the semiconductor dies 102 and 104 may be formed by bonding semiconductor wafers together (e.g., wafer-to-wafer bonding), by bonding dies together (die-to-die) bonding, and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIG. 1A, the semiconductor die 102 may include a device layer 108 and an interconnect layer 110 above the device layer 108. The semiconductor die 104 may include a device layer 112 and an interconnect layer 114 below the device layer 112. The bonding interface 106 may be located between the interconnect layers 110 and 114, and may include portions of each of the interconnect layers 110 and 114. The bonding interface 106 may include conductive structures of the interconnect layers 110 and 114 that are bonded together by metal-to-metal bonds, and/or dielectric layers of the interconnect layers 110 and 114 that are bonded together by dielectric-to-dielectric bonds.

The device layer 108 may correspond to a portion of a semiconductor wafer on which the semiconductor die 102 was formed, and the device layer 112 may correspond to a portion of another semiconductor wafer on which the semiconductor die 104 was formed. The device layers 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layers 108 and 112 may respectively include integrated circuit devices 116 and 118 of the semiconductor dies 102 and 104. The integrated circuit devices 116 and 118 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The interconnect layers 110 and 114 may each include conductive structures that interconnect the integrated circuit devices 116 and 118 of the device layers 108 and 112, respectively. Additionally and/or alternatively, the interconnect layers 110 and 114 may each include conductive structures that electrically connect the semiconductor dies 102 and 104.

The interconnect layer 110 of the semiconductor die 102 includes one or more dielectric layers 120 that are arranged in a direction that is approximately perpendicular to the device layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect layer 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 110 includes a plurality of conductive structures 122 (e.g., electrically conductive structures) in the dielectric layer(s) 120. The conductive structures 122 are electrically coupled and/or physically coupled with one or more of the integrated circuit devices 116 in the device layer 108, and are electrically interconnected together in the interconnect layer 110. The conductive structures 122 correspond to circuit routing that enables signals and/or power to be provided to and/or from the integrated circuit devices 116. The conductive structures 122 may include a combination of conductive structures that extend primarily horizontally in the interconnect layer 110 (e.g., trenches, conductive lines) and that are interconnected by interconnect structures (e.g., vias) that extend primarily vertically in the interconnect layer 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 110 may be arranged in a vertical manner to facilitate electrical signals and/or power to be routed between the device layer 108 and the semiconductor die 104, between integrated circuit devices 116 through the interconnect layer 110, and/or between the integrated circuit devices 116 and the integrated circuit devices 118 in the semiconductor die 104. The conductive structures 122 may be arranged in alternating layers of metallization layers (referred to as “M”-layers) and via layers (referred to as “V”-layers). Each metallization layer may include one or more conductive structures laterally arranged in the interconnect layer 110, and each via layer may include one or more interconnect structures that interconnect the metallization layers in the interconnect layer 110. As an example, a metal-0 (M0) layer may be located at the bottom of the interconnect layer 110 and may be coupled with the integrated circuit devices 116 in the device layer 108, a via-1 (V1) layer may be located above and coupled with the M1 layer in the interconnect layer 110, a metal-1 layer (M1) layer may be located above and coupled with the V1 layer in the interconnect layer 110, a via-2 (V2) layer may be located above and coupled with the M1 layer in the interconnect layer 110, a metal-2 layer (M2) layer may be located above and electrically coupled with the V2 layer in the interconnect layer 110, and so on. In some implementations, the interconnect layer 110 includes nine (9) stacked metallization layers (e.g., M0-M8). In some implementations, the interconnect layer 110 includes another quantity of stacked metallization layers.

At the bonding interface 106, the interconnect layer 110 may include a plurality of bonding pads 124. The bonding pads 124 may be electrically coupled with the conductive structures 122 in the interconnect layer 110 by bonding vias and/or other types of conductive structures. The bonding pads 124 may each include tungsten (W), cobalt (Co), ruthenium (Ru), titanium (Ti), aluminum (Al), copper (Cu), gold (Au), and/or a combination thereof, among other examples of electrically conductive metals.

As further shown in FIG. 1A, the interconnect layer 114 of the semiconductor die 104 may include a similar combination and/or arrangement of structures and/or layers as the interconnect layer 110 of the semiconductor die 102. For example, the semiconductor die 104 may include a combination of one or more dielectric layers 126 and conductive structures 128 in the dielectric layer(s) 126. Moreover, the interconnect layer 114 may include bonding pads 130 that are electrically coupled with one or more of the conductive structures 128 (e.g., by bonding vias and/or other types of conductive structures). These layers and/or structures may have a reversed vertical arrangement relative to the semiconductor die 102, which enables the semiconductor die 102 and the semiconductor die 104 to be bonded at the bonding interface 106 such that the interconnect layer 110 and the interconnect layer 114 are facing each other.

At the bonding interface 106, the bonding pads 124 of the semiconductor die 102 and the bonding pads 130 of the semiconductor die 104 are directly bonded by metal-to-metal bonds. Moreover, a dielectric layer of the one or more dielectric layers 120 of the semiconductor die 102 and a dielectric layer of the one or more dielectric layers 126 of the semiconductor die 104 are directly bonded by dielectric-to-dielectric bonds.

As further shown in FIG. 1A, the semiconductor die 104 may include another interconnect layer 132. The interconnect layer 114 may be located on a first side of the device layer 112 of the semiconductor die 104, and the interconnect layer 132 may be located on a second side of the device layer 112 opposing the first side. The interconnect layer 114 may be configured to route signals and/or power between the semiconductor dies 102 and 104, and/or may be configured to route signals and/or power between integrated circuit devices 118 of the semiconductor die 104. The interconnect layer 132 may be configured to route signals and/or power between the semiconductor die 104 and devices external to the semiconductor die package 100. For example, the interconnect layer 132 may be configured to route signals and/or power between the semiconductor die 104 and an external high bandwidth memory (HBM) die, an external system on chip (SoC) die, an external input/output (I/O) die, and/or another type of device external to the semiconductor die package 100.

The interconnect layer 132 of the semiconductor die 104 includes one or more dielectric layers 134 (e.g., ILD layers, IMD layers, ESLs) and conductive structures 136 (e.g., trenches, metallization layers, vias, interconnect structures) in the dielectric layer(s) 134. The dielectric layer(s) 134 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material. The conductive structures 136 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect layer 132 further includes connection structures 138 that enable the semiconductor die package 100 to be attached to a substrate (e.g., an interposer, a printed circuit board (PCB)), another semiconductor die package, and/or to be attached to another structure. The connection structures 138 may include bonding pads and/or another type of connection structures.

As further shown in FIG. 1A, the semiconductor die package 100 includes one or more elongated conductive structures 140 that extend between the interconnect layer 114 and 132 through the device layer 112 of the semiconductor die 104. The elongated conductive structure(s) 140 include TSVs, metal pillars, metal columns, and/or other types of vertically elongated conductive structures (e.g., conductive pillars, conductive vias) that each physically connect and electrically connect with a conductive structure 128 (e.g., a metal pad) in the interconnect layer 114 at a first end, and that each physically connect and electrically connect with a conductive structure 136 (e.g., a metal pad) in the interconnect layer 132. The elongated conductive structure(s) 140 may be referred to as TSV structures in that the elongated conductive structure(s) 140 extend fully through a semiconductor layer (e.g., a silicon substrate) of the device layer 112 as opposed to extending fully through a dielectric layer or an insulator layer. The elongated conductive structure(s) 140 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The conductive structures 128, the conductive structures 136, and the elongated conductive structure(s) 140 may each include a metal material that is susceptible to diffusion into the dielectric layers 126, 134, and/or into the semiconductor layer of the device layer 112. Accordingly, barrier layers 142 may be included between one or more conductive structures 128 and the dielectric layer(s) 126 in the interconnect layer 114 (including the metallization layer(s) 128 to which the elongated conductive structure(s) 140 are connected). Similarly, barrier layers 144 may be included between one or more conductive structures 136 and the dielectric layer(s) 134 in the interconnect layer 132 (including the conductive structures(s) 136 to which the elongated conductive structure(s) 140 are connected). Moreover, barrier layers 146 may be included between the elongated conductive structure(s) 140 and the dielectric layer(s) 126, between the elongated conductive structure(s) 140 and the dielectric layer(s) 134, and between the elongated conductive structure(s) 140 and the semiconductor layer of the device layer 112.

The barrier layers 142, 144, and 146 each include one or more materials that are capable of blocking or inhibiting the diffusion of metal atoms (e.g., copper atoms) into the dielectric layers 126, 134, and/or into the semiconductor layer of the device layer 112. Examples of such materials include tantalum nitride (TaN) and/or titanium nitride (TiN), among other examples.

FIG. 1B illustrates a close-up view of the elongated conductive structures 140 and the associated conductive structures 128 and 136, along with the barrier layers 142, 144, and 146. As shown in FIG. 1B, the barrier layers 142 may be included between the sidewalls of the conductive structure(s) 128 and the dielectric layer(s) 126. The barrier layers 144 may be included between the sidewalls of the conductive structure(s) 136 and the dielectric layer(s) 134. The barrier layers 146 may be included between the sidewalls of the elongated conductive structure(s) 140 and the dielectric layer(s) 126, between the sidewalls of the elongated conductive structure(s) 140 and the dielectric layer(s) 134, and between the sidewalls of the elongated conductive structure(s) 140 and the semiconductor layer of the device layer 112.

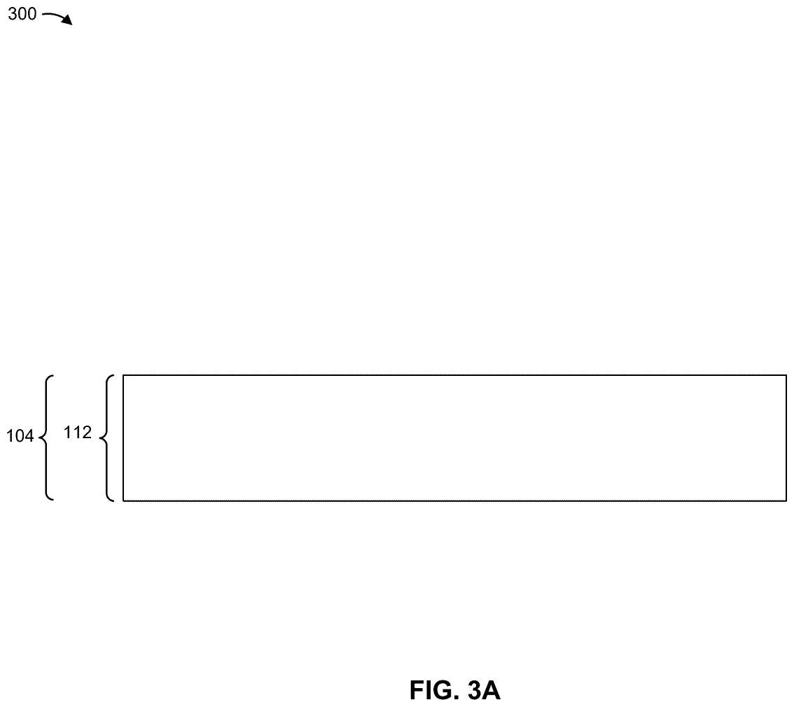

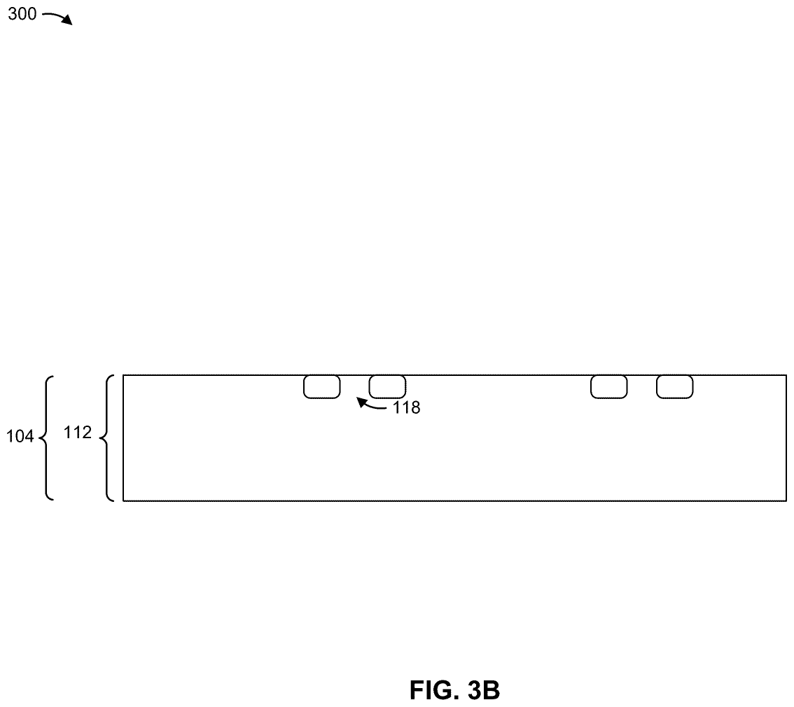

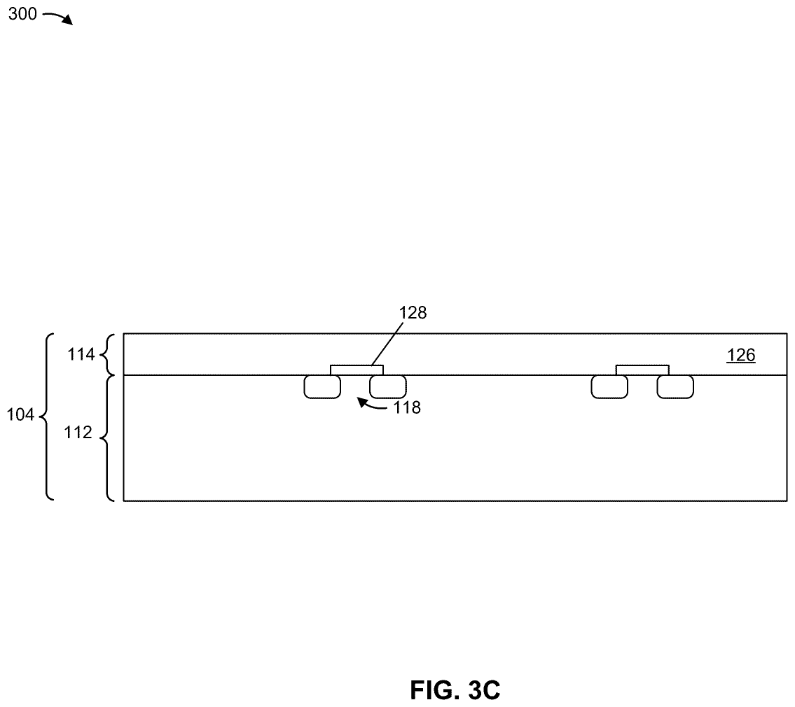

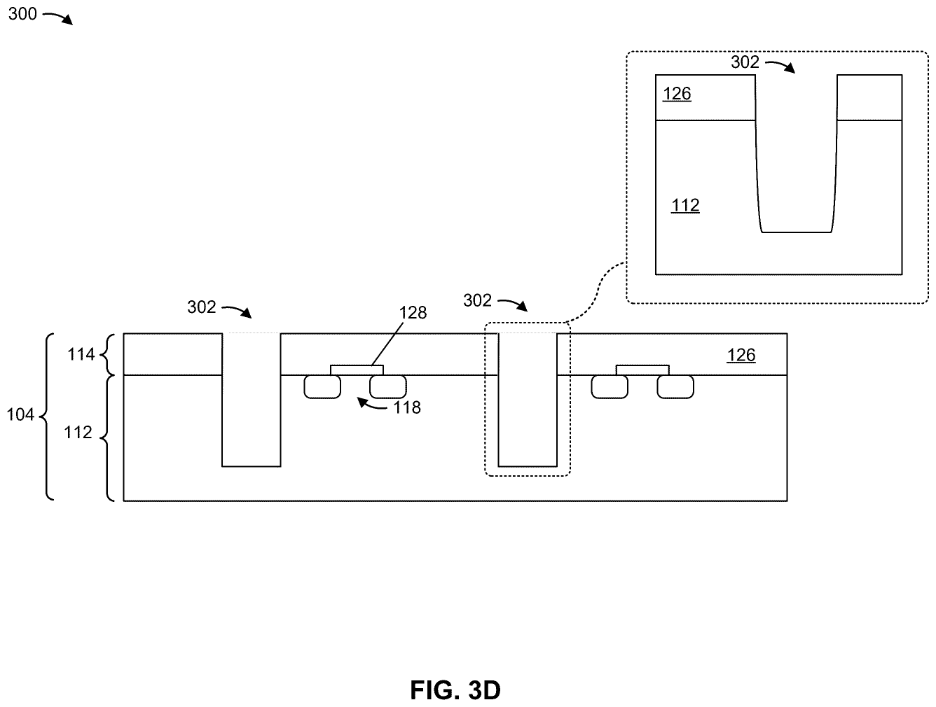

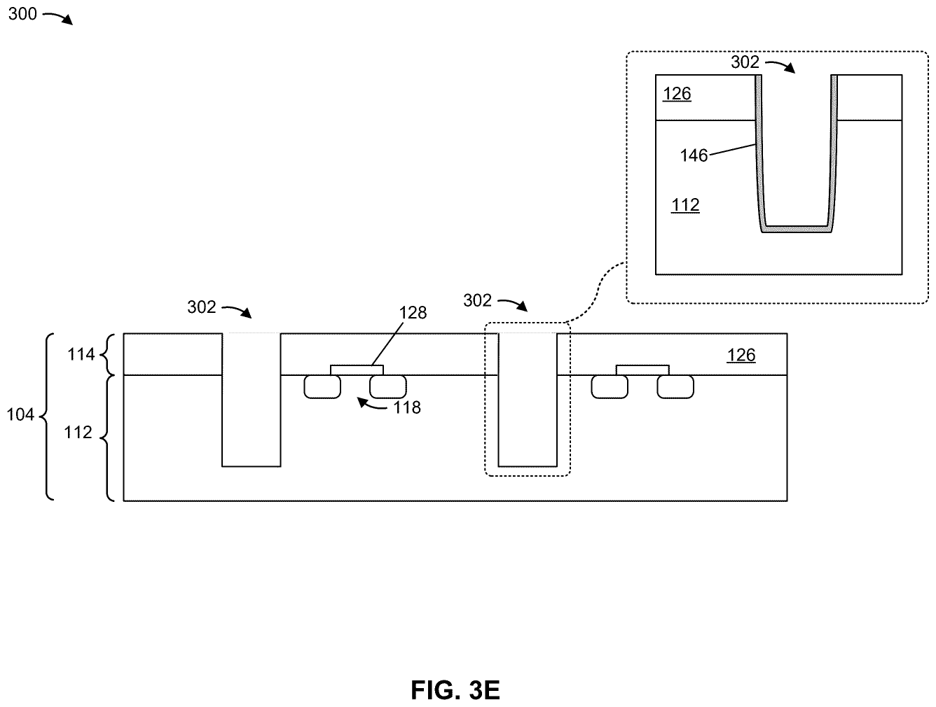

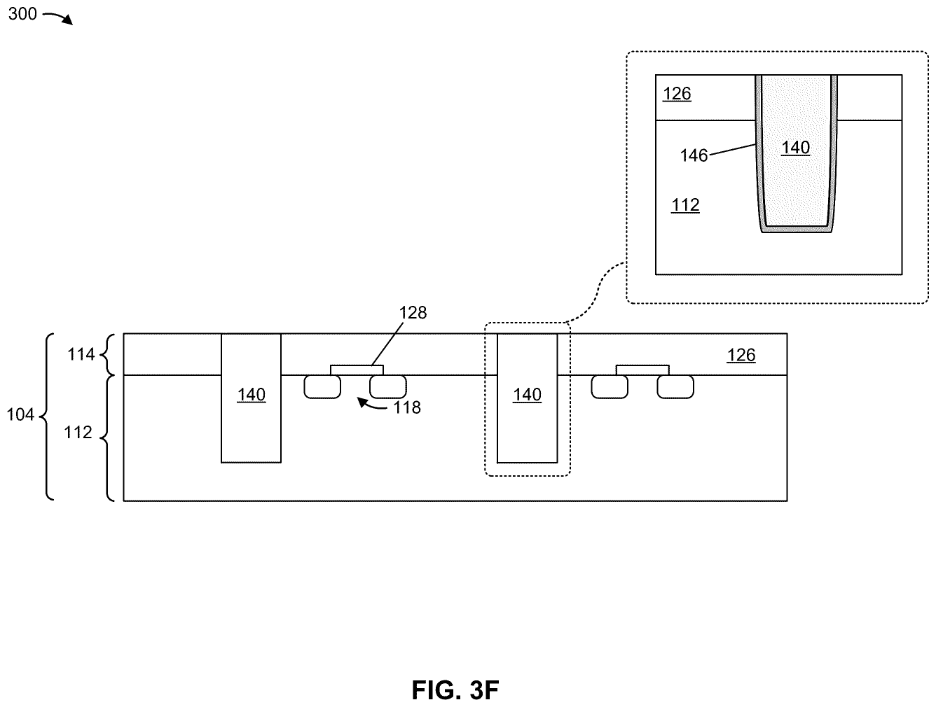

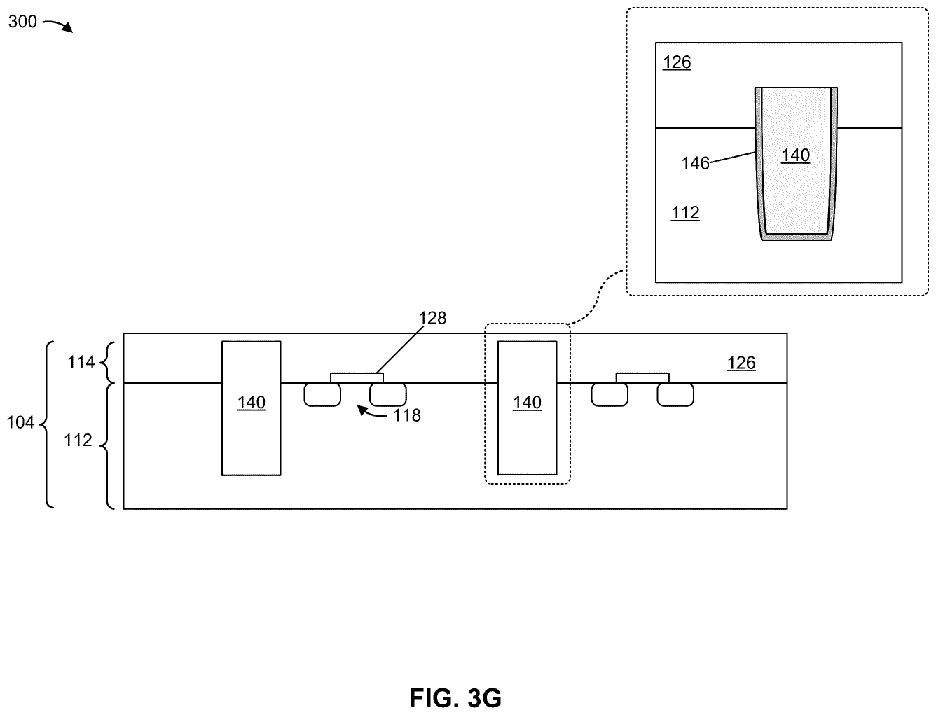

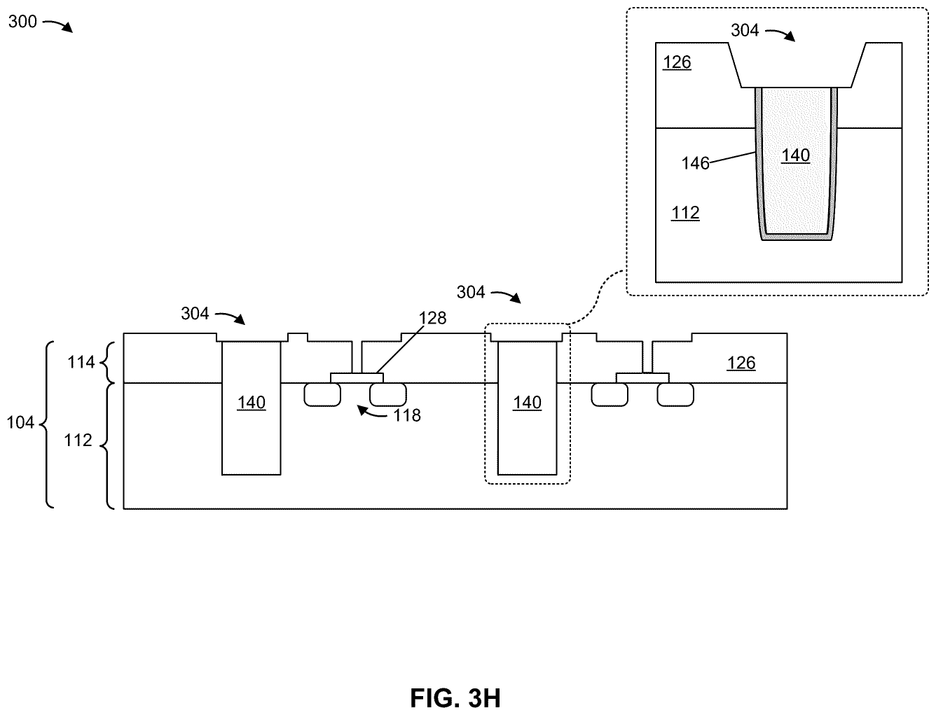

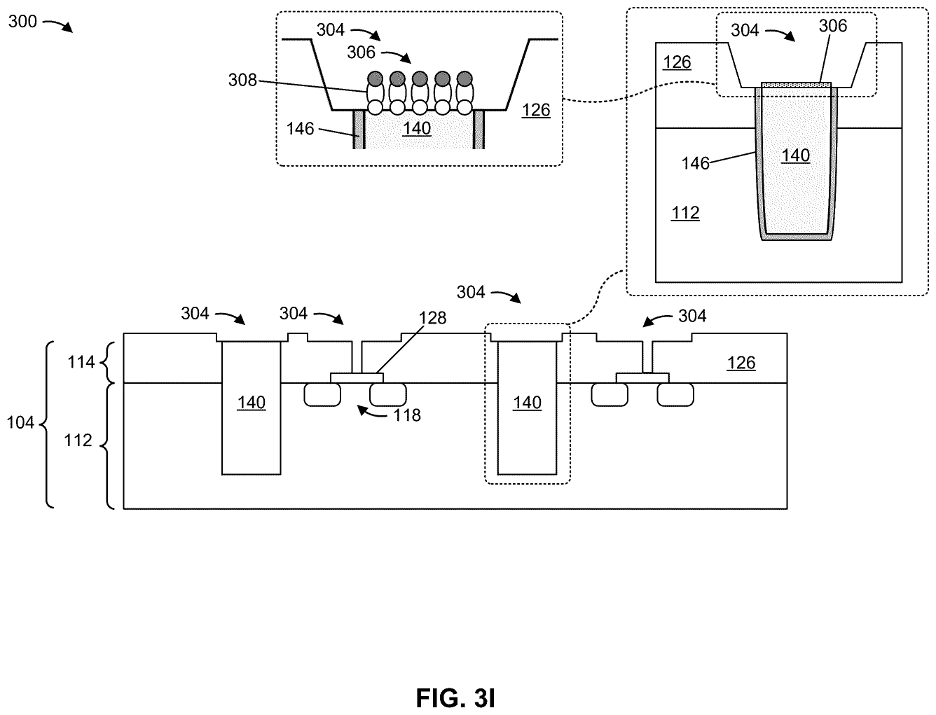

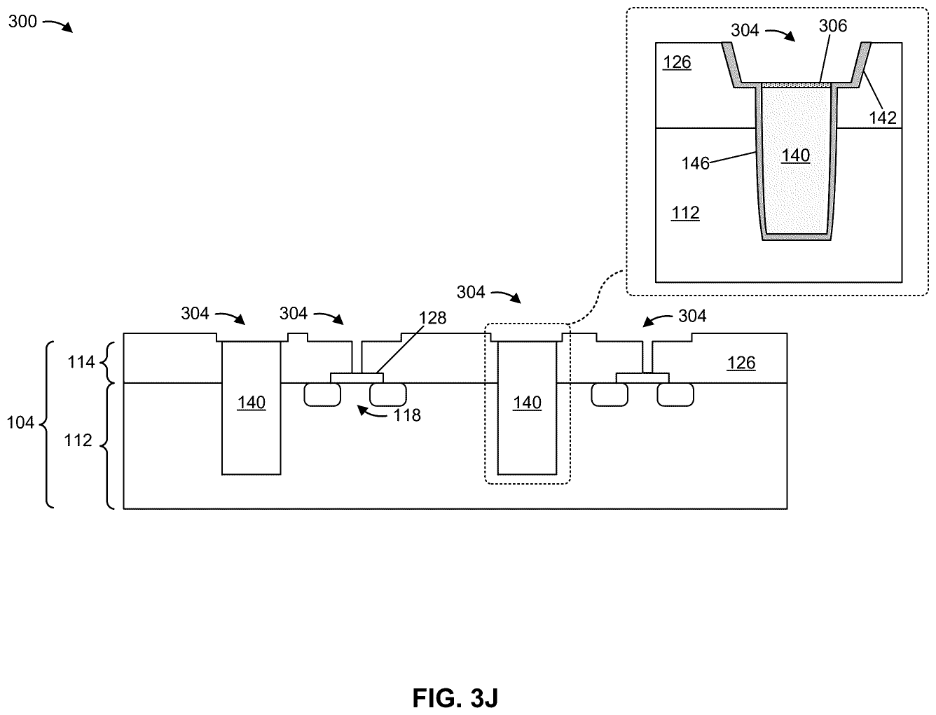

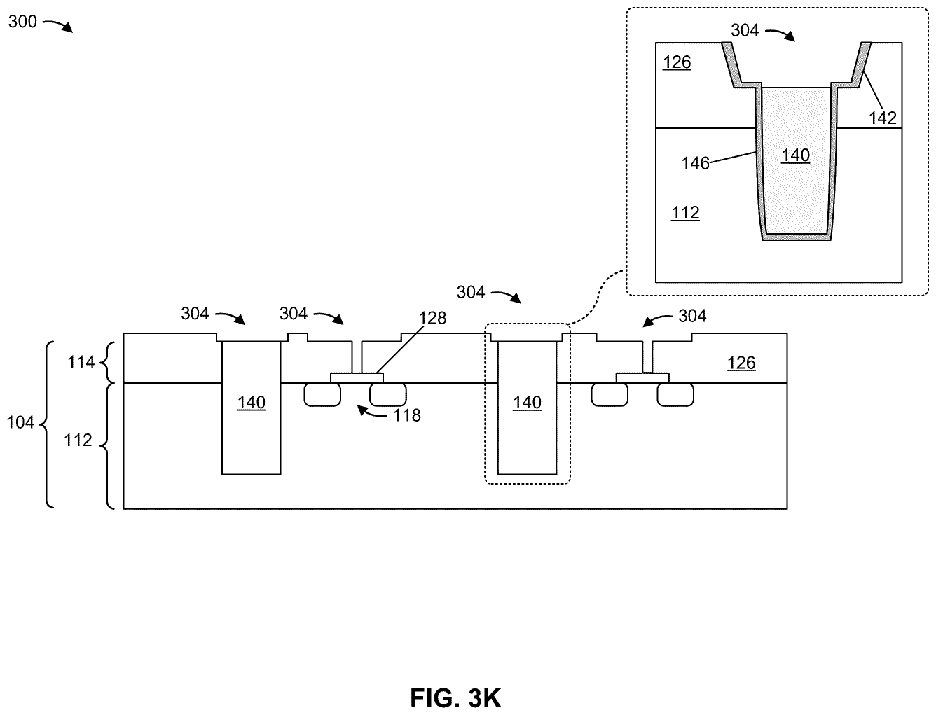

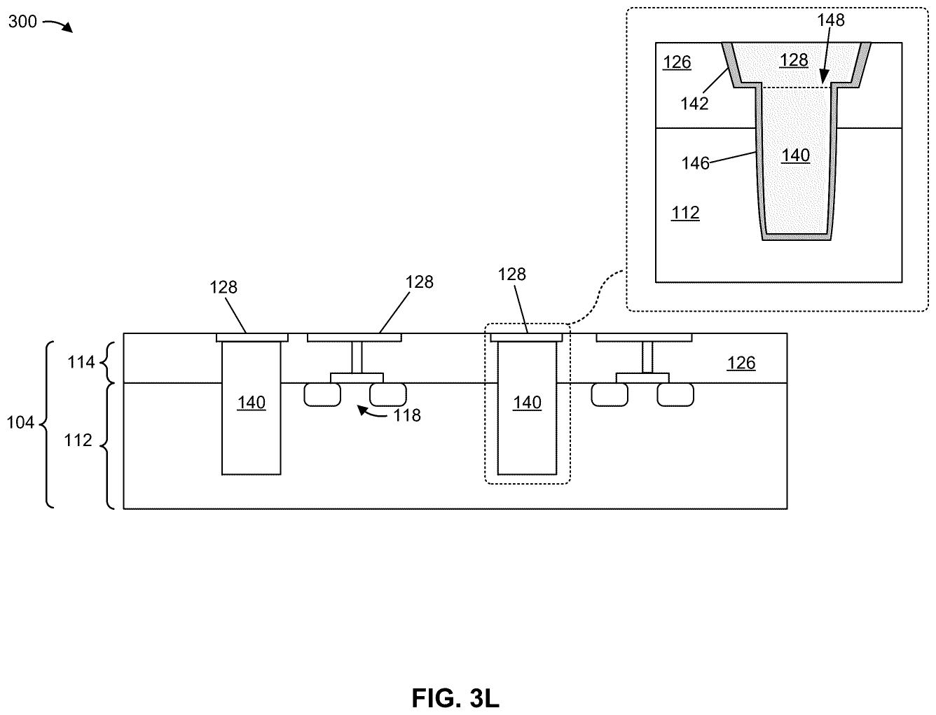

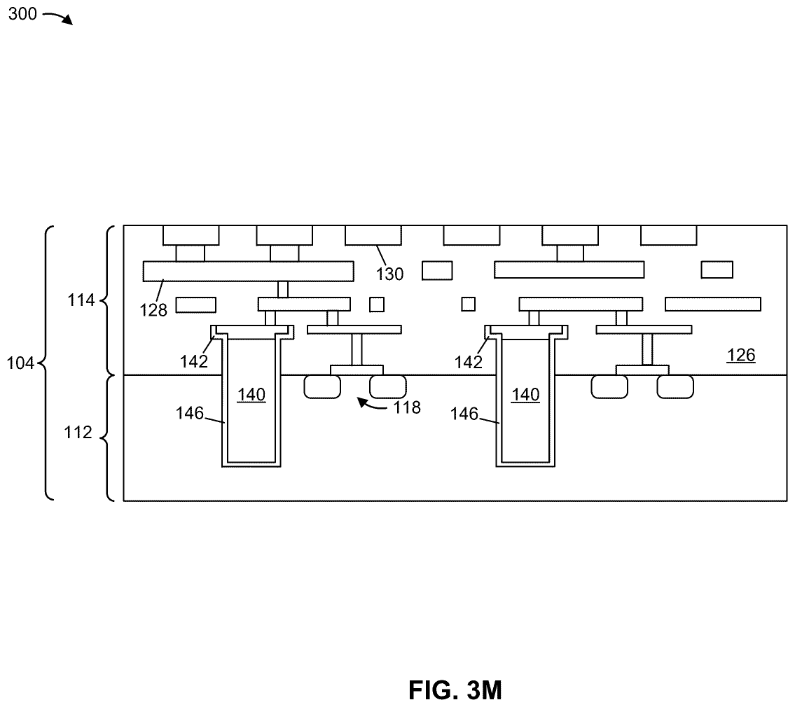

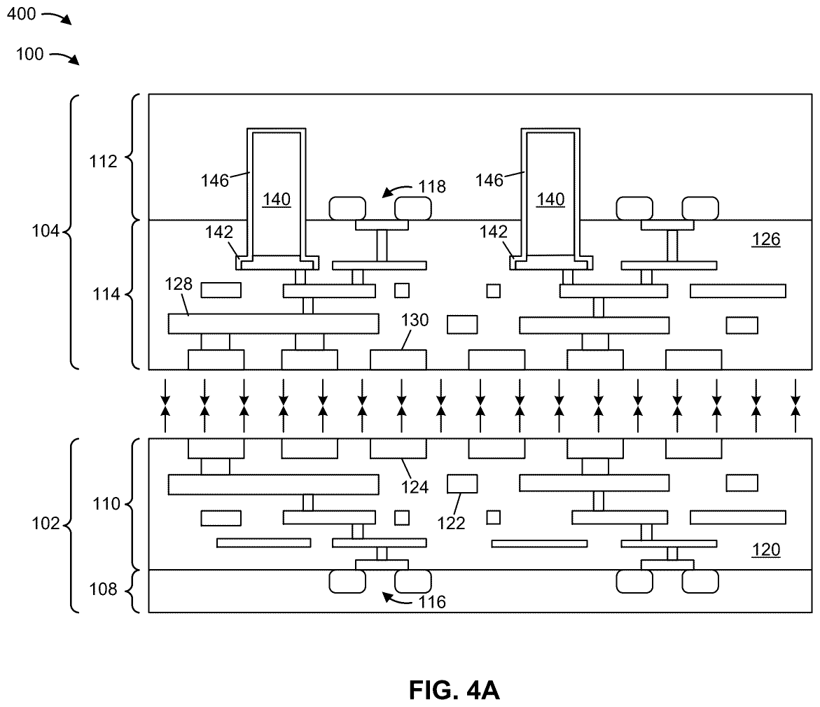

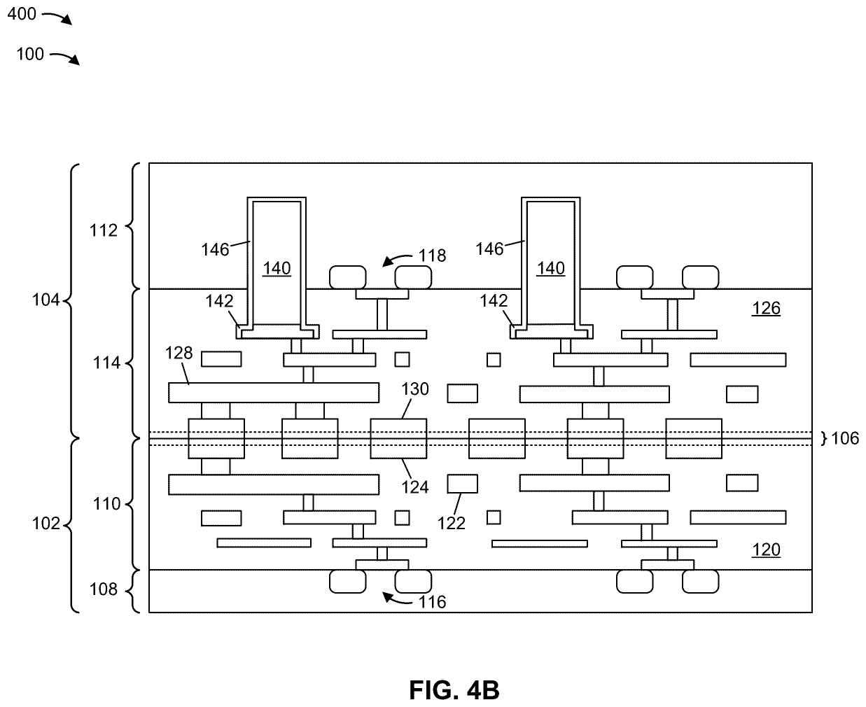

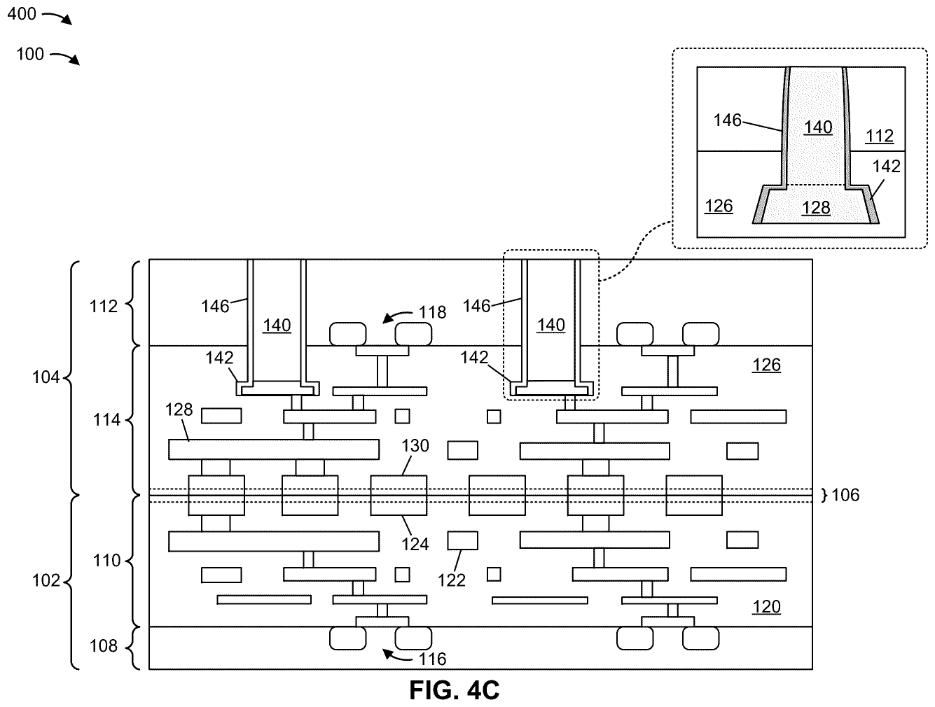

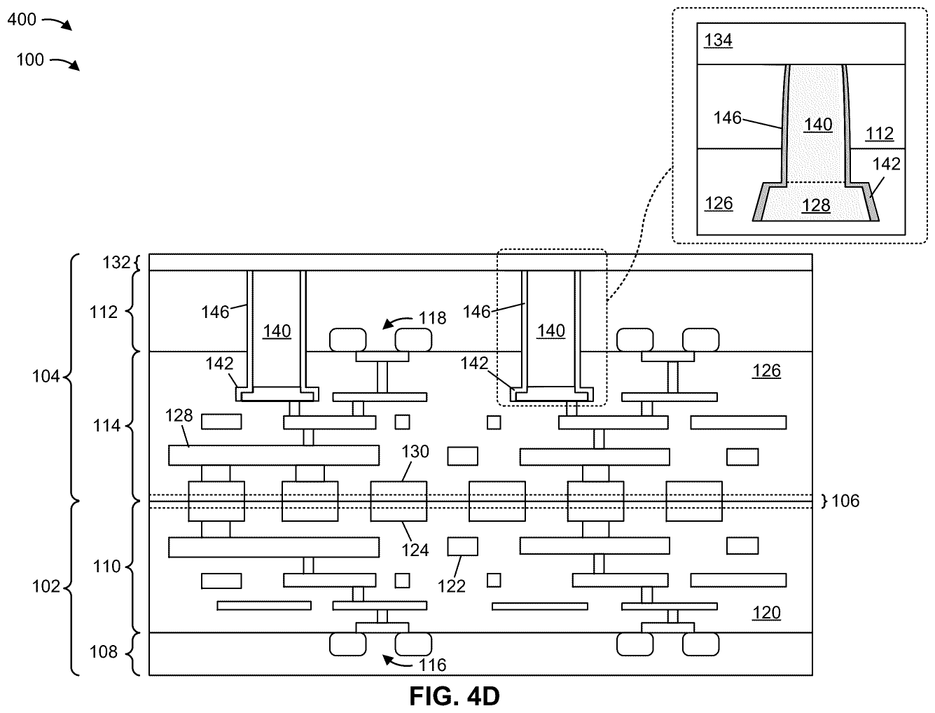

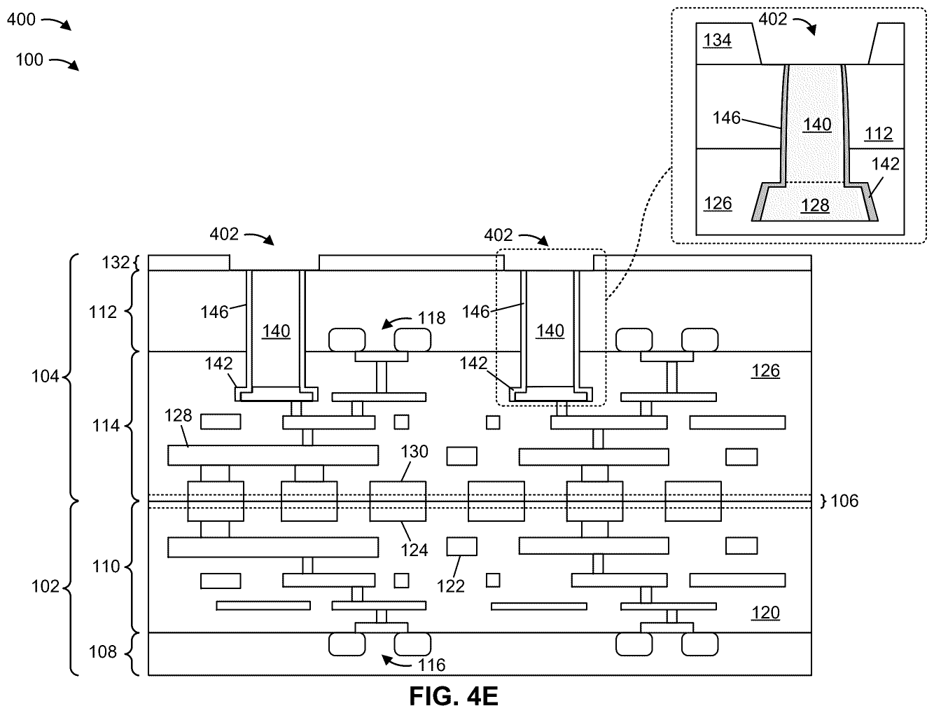

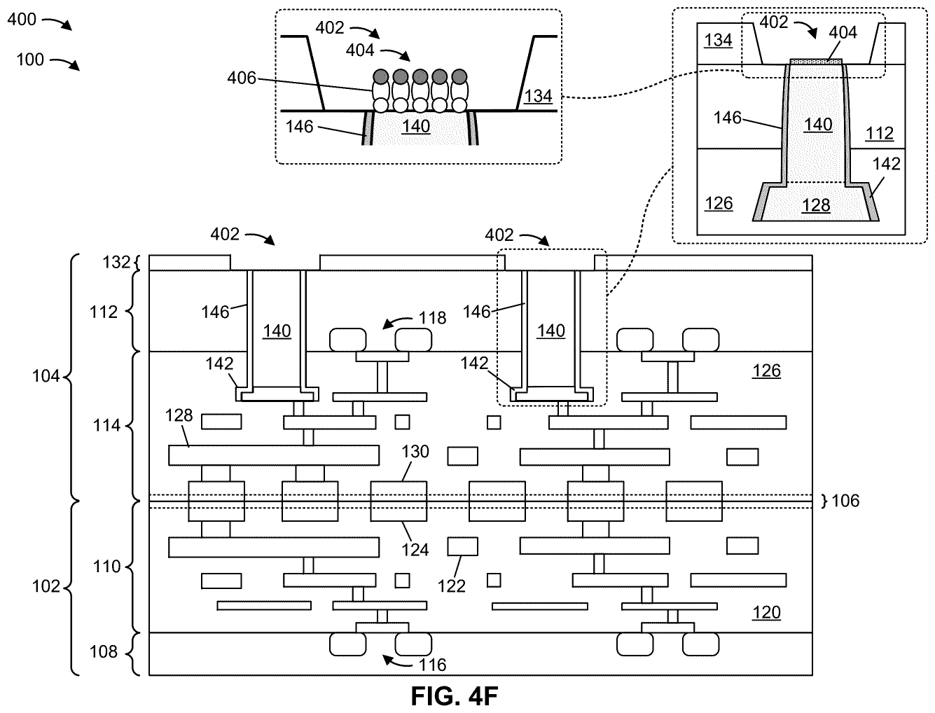

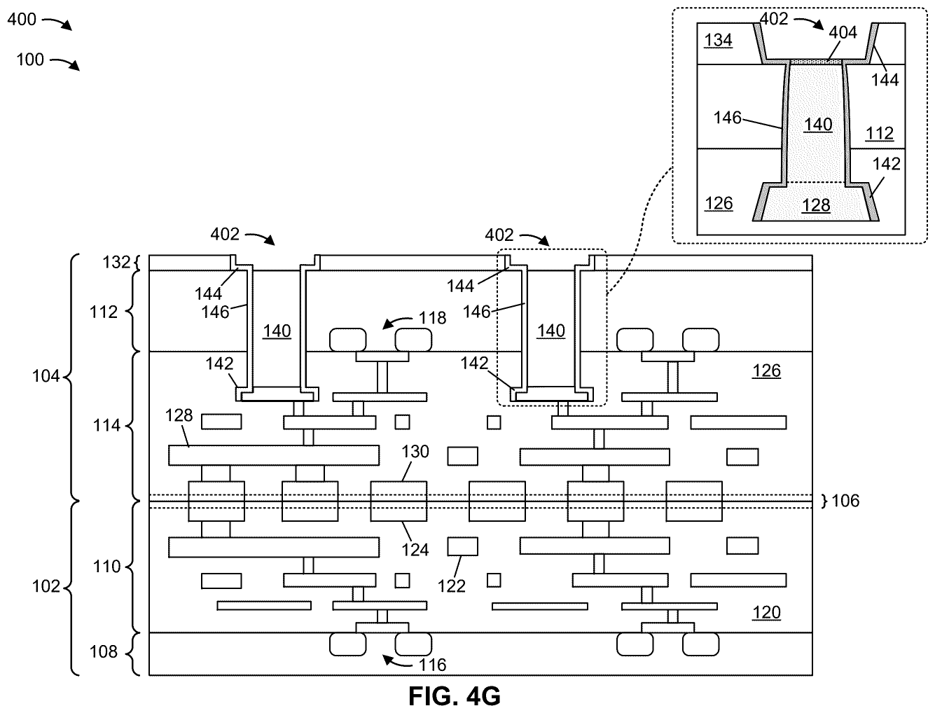

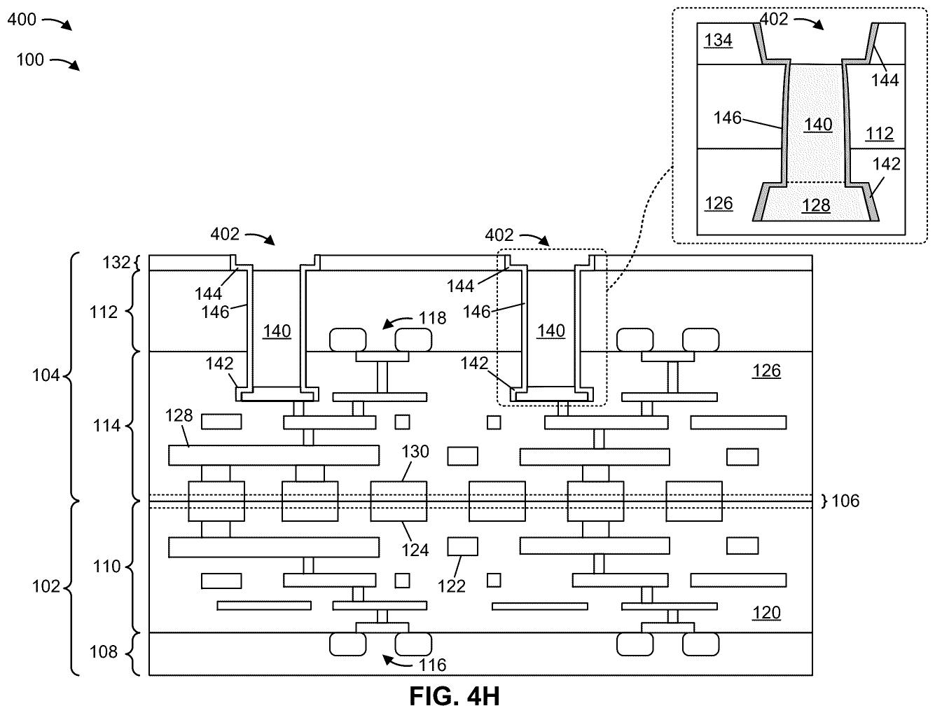

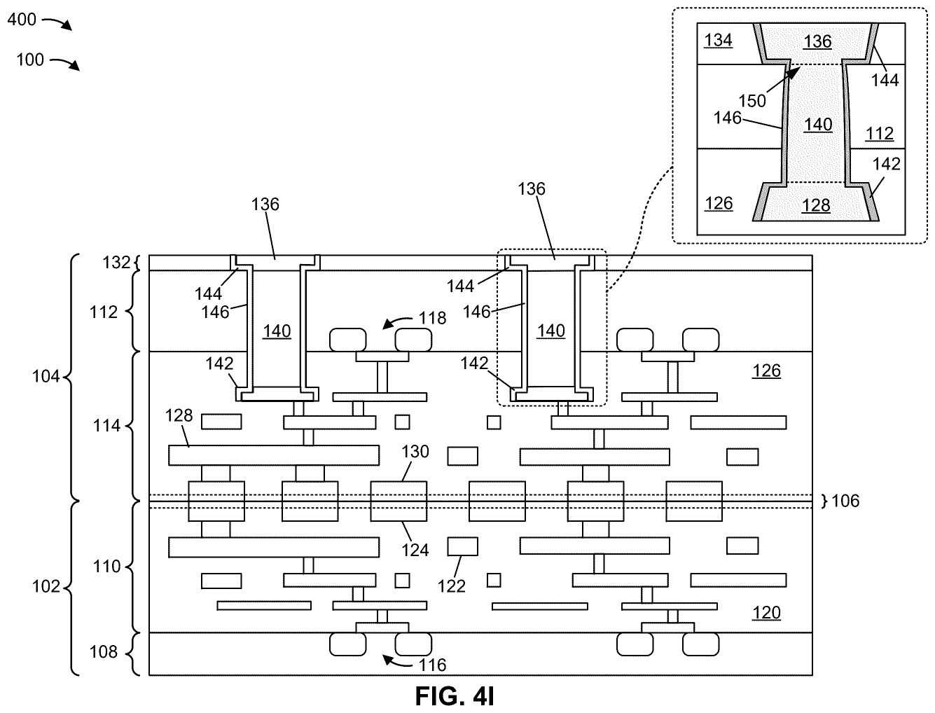

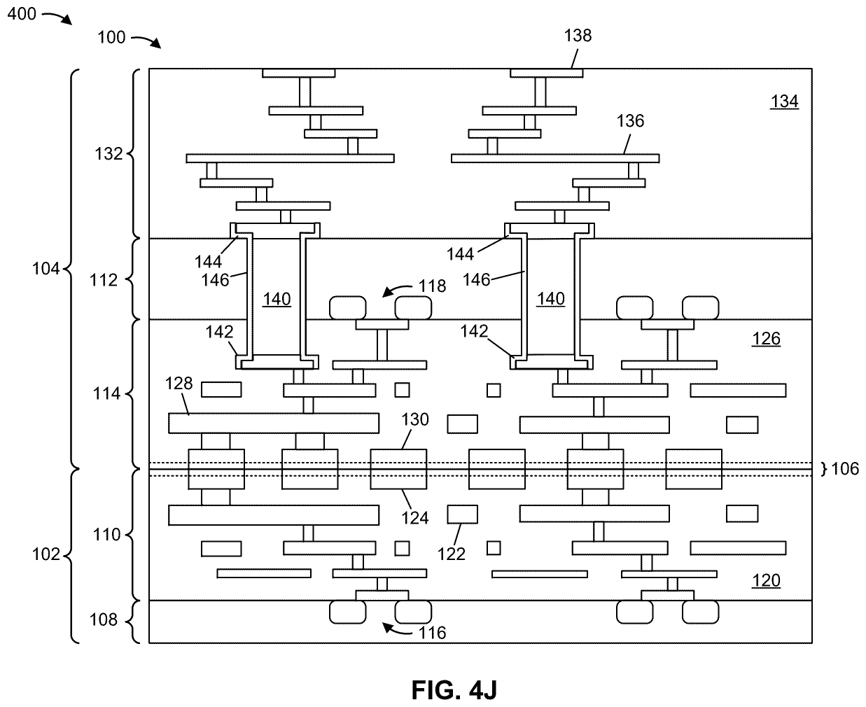

As described below in connection with FIGS. 3A-3M and 4A-4J, the barrier layers 142, 144, and 146 for the elongated conductive structures 140 and the associated conductive structures 128 and 136 are formed in a manner such that the barrier layers 142, 144, and 146 are not included at the interfaces between the elongated conductive structures 140 and the associated conductive structures 128 and 136. In other words, barrier layers 142, 144, and 146 are formed such that the material of an elongated conductive structure 140 is in direct physical contact with the material of an associated conductive structure 128 (e.g., with no intervening barrier layer), and such that the material of the elongated conductive structure 140 is in direct physical contact with the material of an associated conductive structure 136 (e.g., with no intervening barrier layer). Thus, an interface 148 between the elongated conductive structure 140 and the associated conductive structure 128 is a direct metal-to-metal connection (e.g., a direct copper-to-copper connection), and an interface 150 between the elongated conductive structure 140 and the associated conductive structure 136 is a direct metal-to-metal connection (e.g., a direct copper-to-copper connection). This enables a low contact resistance to be achieved between the elongated conductive structure 140 and the associated conductive structure 128, and between the elongated conductive structure 140 and the associated conductive structure 136. In particular, the electrical resistivity of the material of each of the barrier layers 142, 144, and 146 is higher than the electrical resistivity of the material of the elongated conductive structure 140 and the associated conductive structures 128 and 136. Forming the barrier layers 142, 144, and 146 such that the barrier layers 142, 144, and 146 are not included between the connections between the elongated conductive structure 140 and the associated conductive structures 128 and 136 prevents the barrier layers 142, 144, and 146 from increasing the electrical resistance between the elongated conductive structure 140 and the associated conductive structures 128 and 136.

As further shown in FIG. 1B, an elongated conductive structure 140 may have a cross-sectional profile in which the elongated conductive structure 140 is tapered between the associated conductive structure 128 and the associated conductive structure 136. The direction of the taper may depend on when, in the manufacturing process of the semiconductor die package 100, the elongated conductive structure 140 is formed. For example, the elongated conductive structure 140 may have a dimension D1 corresponding to a cross-sectional width of the elongated conductive structure 140 at the interface 150 between the elongated conductive structure 140 and an associated conductive structure 136, and may have a dimension D2 corresponding to a cross-sectional width of the elongated conductive structure 140 at the interface 148 between the elongated conductive structure 140 at an associated conductive structure 128. In implementations in which the elongated conductive structure 140 is formed during manufacturing of the interconnect layer 114, the dimension D2 may be greater than the dimension D1, and the cross-sectional width of the elongated conductive structure decreases from the interface 148 to the interface 150. This is due to the recess, for the elongated conductive structure 140, being formed in the direction from the interconnect layer 114 into the device layer 112. Etching in this direction results in the top of the recess in the interconnect layer 114 having a greater cross-sectional width than the cross-sectional width of the recess in the device layer 112.

Alternatively, the elongated conductive structure 140 is formed during manufacturing of the interconnect layer 132, in which case the dimension D1 may be greater than the dimension D2 due to the recess for the elongated conductive structure 140 being etched from the interconnect layer 132 and into the interconnect layer 114 through the device layer 112.

In some implementations, the dimension D1 may be included in a range of approximately 10 nanometers to approximately 100 nanometers. If the dimension D1 is less than approximately 10 nanometers, voids may form in the elongated conductive structure 140 because of poor copper gap-filling performance. If the dimension D1 is greater than approximately 100 nanometers, the density of integrated circuit devices 118 in the device layer 112 may be negatively affected. If the dimension D1 is included in the range of approximately 10 nanometers to approximately 100 nanometers, the likelihood of void formation in the elongated conductive structure 140 may be minimized, while enabling a high density of integrated circuit devices 118 to be achieved in the device layer 112. However, other values for the dimension D1, and ranges other than approximately 10 nanometers to approximately 100 nanometers, are within the scope of the present disclosure.

In some implementations, the dimension D2 may be included in a range of approximately 10 nanometers to approximately 100 nanometers. If the dimension D2 is less than approximately 10 nanometers, voids may form in the elongated conductive structure 140 because of poor copper gap-filling performance. If the dimension D2 is greater than approximately 100 nanometers, the density of integrated circuit devices 118 in the device layer 112 may be negatively affected. If the dimension D2 is included in the range of approximately 10 nanometers to approximately 100 nanometers, the likelihood of void formation in the elongated conductive structure 140 may be minimized, while enabling a high density of integrated circuit devices 118 to be achieved in the device layer 112. However, other values for the dimension D2, and ranges other than approximately 10 nanometers to approximately 100 nanometers, are within the scope of the present disclosure.

Another example dimension D3 of the semiconductor die 104 includes a thickness or vertical direction length of the elongated conductive structure 140. In some implementations, the dimension D3 is included in a range of approximately 50 nanometers to approximately 150 nanometers. In some implementations, a ratio of the dimension D3 to the dimension D1 is included in a range of approximately 1.5:1 to approximately 5:1. However, other values for the range are within the scope of the present disclosure. In some implementations, a ratio of the dimension D3 to the dimension D2 is included in a range of approximately 1.5:1 to approximately 5:1. However, other values for the range are within the scope of the present disclosure.

Another example dimension D4 of the semiconductor die 104 includes an angle between a sidewall of the elongated conductive structure 140 and a bottom surface of the associated conductive structure 136. In some implementations, the dimension D4 is included in a range of greater than approximately 60 degrees and less than approximately 90 degrees. However, other values for the range are within the scope of the present disclosure. Another example dimension D5 of the semiconductor die 104 includes an angle between a sidewall of the elongated conductive structure 140 and a bottom surface of the associated conductive structure 128. In some implementations, the dimension D5 is included in a range of greater than approximately 90 degrees and less than approximately 120 degrees. However, other values for the range are within the scope of the present disclosure. In some implementations, a difference between the dimension D5 and the dimension D4 is included in a range of approximately 0 degrees to approximately 10 degrees. However, other values for the range are within the scope of the present disclosure.

As indicated above, FIGS. 1A and 1B are provided as an example. Other examples may differ from what is described with regard to FIGS. 1A and 1B.

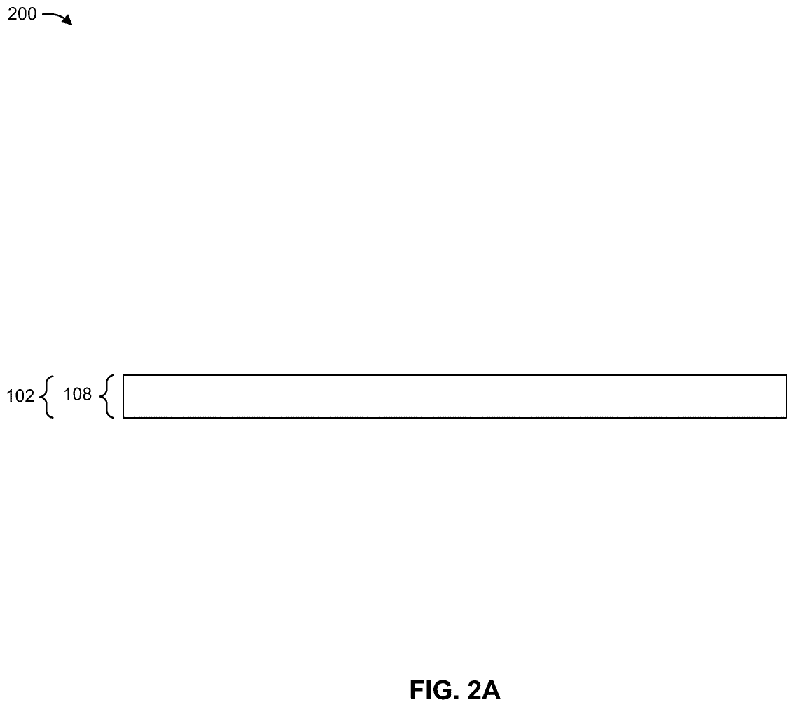

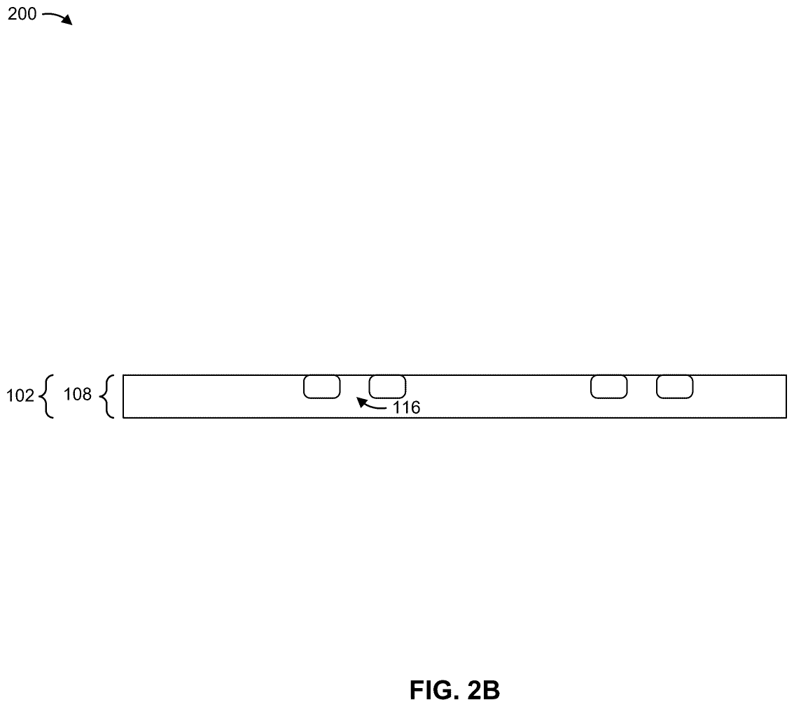

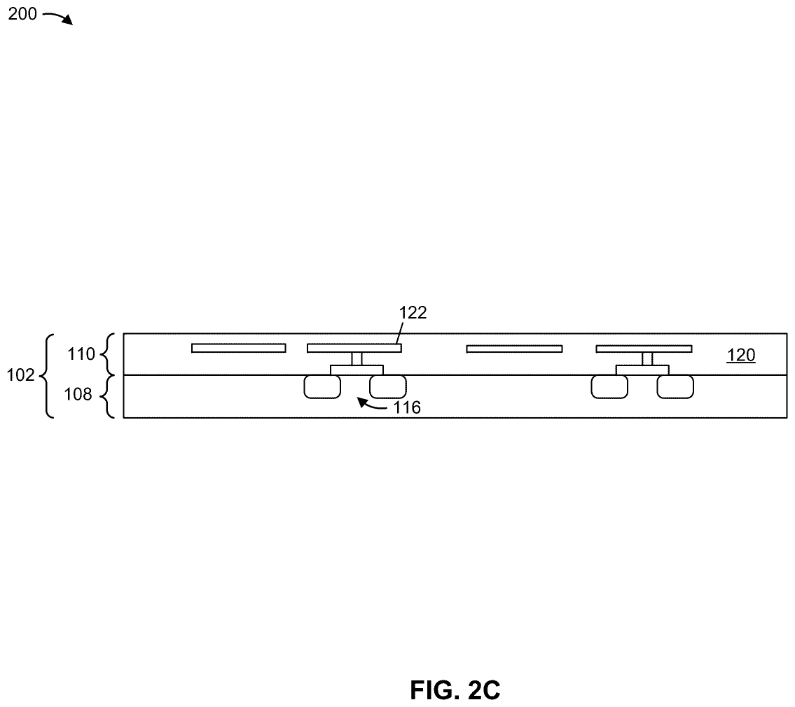

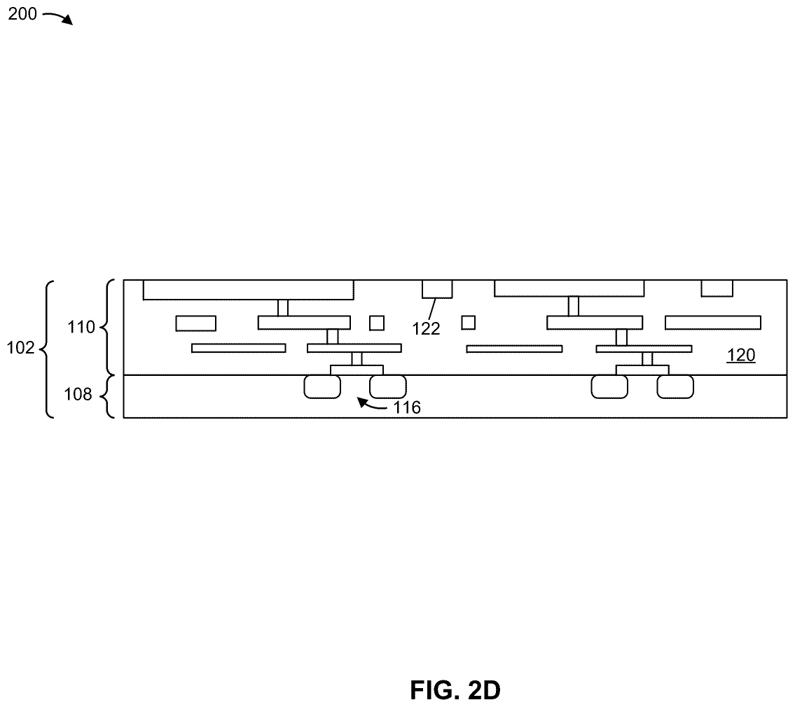

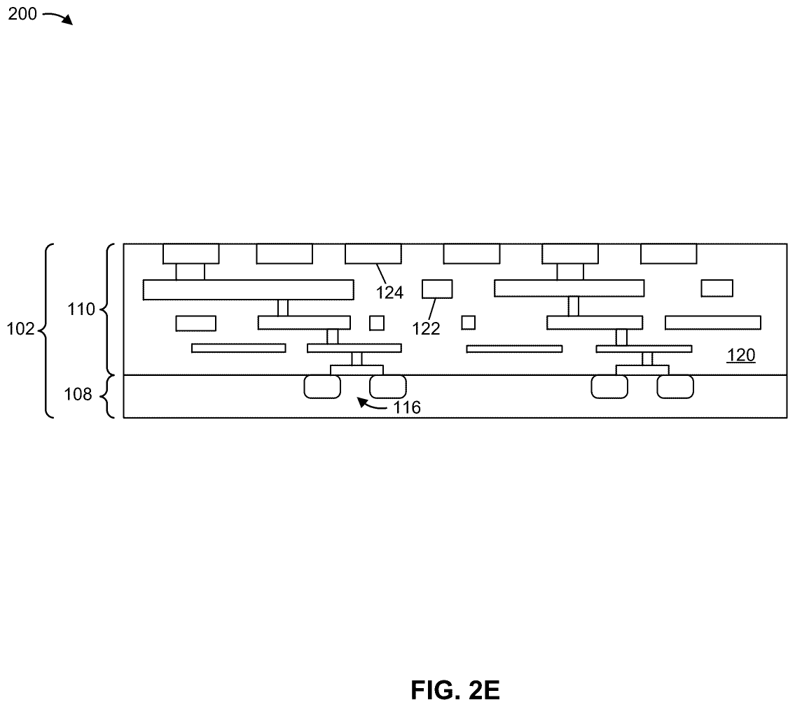

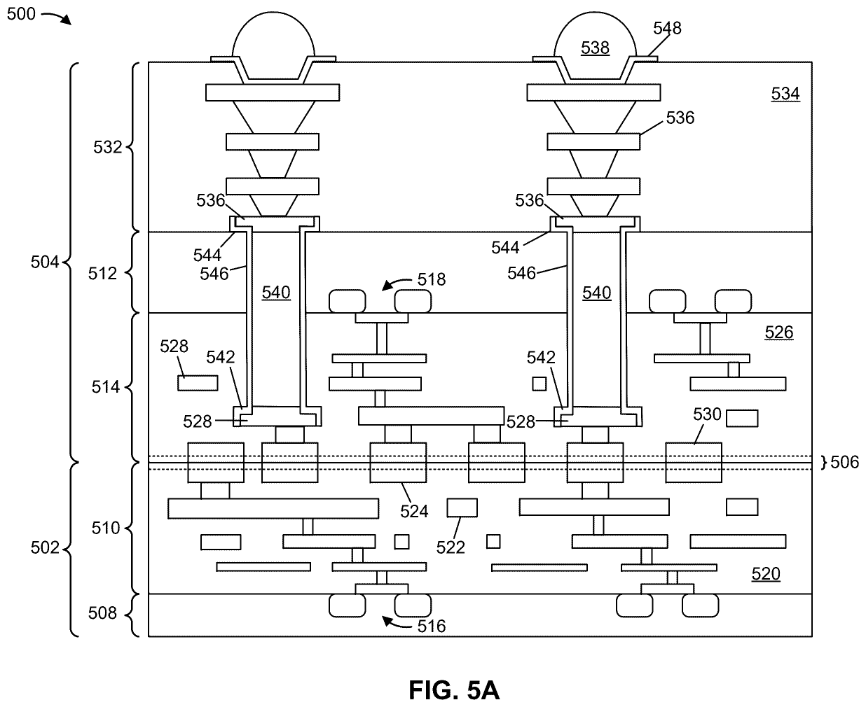

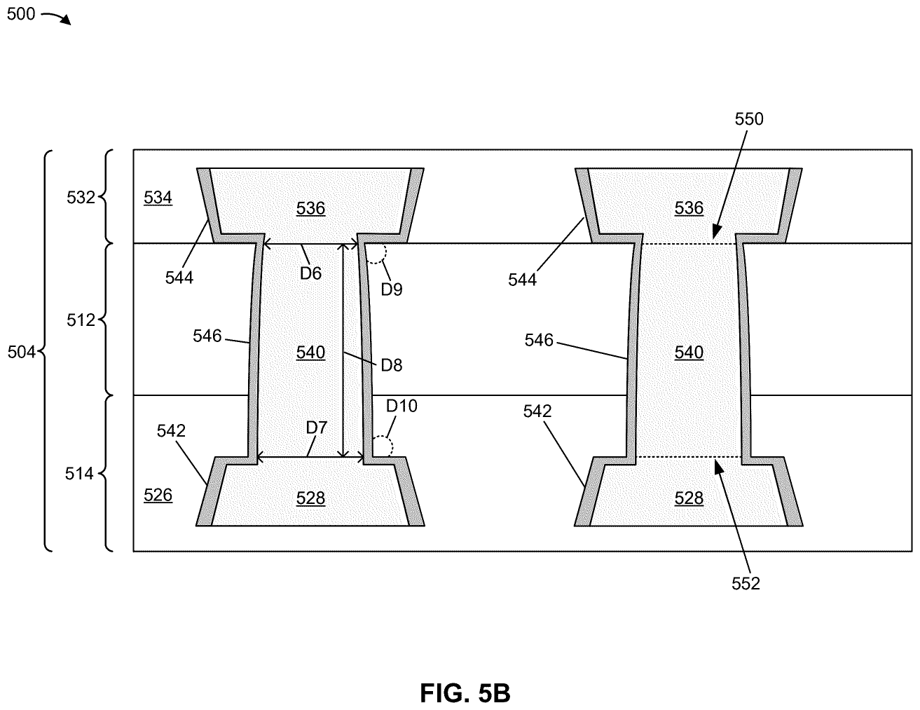

FIGS. 2A-2E are diagrams of an example implementation 200 of forming a semiconductor die described herein. In some implementations, the example implementation 200 includes an example process for forming the semiconductor die 102 or a portion thereof. In some implementations, one or more of the operations described in connection with the example implementation 200 may be performed to form another semiconductor die described herein, such as a semiconductor die 502 illustrated in FIG. 5A. In some implementations, one or more semiconductor processing tools may be used to perform one or more of the operations described in connection with the example implementation 200, such as a deposition tool, an exposure tool, a developer tool, an etch tool, a planarization tool, a plating tool, and/or another type of semiconductor processing tool.

Turning to FIG. 2A, one or more of the operations in the example implementation 200 may be performed in connection with the semiconductor layer of the device layer 108 of the semiconductor die 102. The semiconductor layer of the device layer 108 may be provided in the form of a semiconductor wafer or another type of semiconductor substrate.

As shown in FIG. 2B, the integrated circuit devices 116 may be formed in and/or on the device layer 108 of the semiconductor die 102. One or more semiconductor processing tools may be used to form one or more portions of the integrated circuit devices 116. For example, a deposition tool may be used to perform various deposition operations to deposit layers of the integrated circuit devices 116, and/or to deposit photoresist layers for etching the semiconductor layer of the device layer 108 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 116. As another example, a planarization tool may be used to planarize portions of the integrated circuit devices 116. As another example, an ion implantation tool may be used to implant ions in the semiconductor layer to dope portions of the semiconductor layer of the device layer 108 with one or more types of dopants (e.g., p-type dopants, n-type dopants).

As shown in FIGS. 2C-2E, the interconnect layer 110 of the semiconductor die 102 may be formed over and/or on the device layer 108. One or more semiconductor processing tools may be used to form the interconnect layer 110 by forming one or more dielectric layers 120 and forming a plurality of conductive structures 122 in the dielectric layer(s) 120. For example, a deposition tool may be used to deposit a first layer of the dielectric layer(s) 120 (e.g., using a chemical vapor deposition (CVD) technique, an atomic layer deposition (ALD) technique, a physical vapor deposition (PVD) technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 122 in the recesses (e.g., using a CVD technique, an ALD technique, a PVD technique, an electroplating technique, and/or another type of deposition technique). At least a portion of the first layer of conductive structures 122 may be electrically connected and/or physically connected with the integrated circuit devices 116 in the device layer 108 (e.g., directly connected or connected through contacts). Similar processing operations may be performed to form additional layers of the interconnect layer 110 until a sufficient or desired arrangement of conductive structures 122 is achieved.

As shown in FIG. 2E, bonding pads 124 may be formed in the interconnect layer 110. The bonding pads 124 may be formed in a dielectric layer of the dielectric layer(s) 120. The dielectric layer may be a bonding dielectric layer. The bonding pads 124 may be formed on bonding vias in the interconnect layer 110, and the bonding vias may electrically connect the bonding pads 124 with one or more of the conductive structures 122 in the interconnect layer 110.

As indicated above, FIGS. 2A-2E are provided as an example. Other examples may differ from what is described with regard to FIGS. 2A-2E.

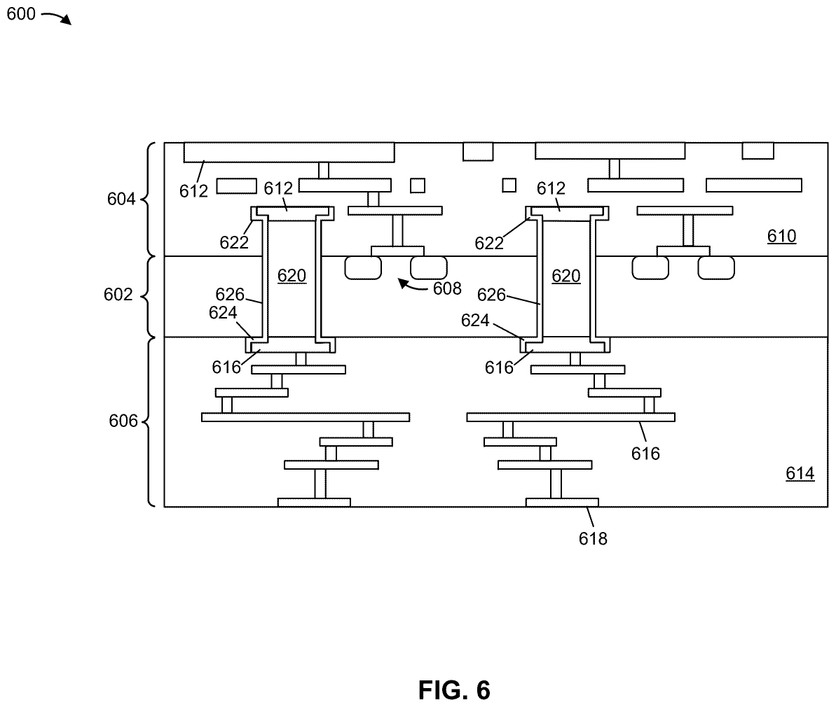

FIGS. 3A-3M are diagrams of an example implementation 300 of forming a semiconductor die described herein. In some implementations, the example implementation 300 includes an example process for forming the semiconductor die 104 or a portion thereof. In some implementations, one or more of the operations described in connection with the example implementation 300 may be performed to form another semiconductor die described herein, such as a semiconductor die 504 illustrated in FIG. 5A. In some implementations, one or more of the operations described in connection with the example implementation 300 may be performed to form a portion of a semiconductor die package described herein, such as a semiconductor die package 600 illustrated in FIG. 6. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 300 may be performed in connection with the semiconductor layer of the device layer 112 of the semiconductor die 104. The semiconductor layer of the device layer 112 may be provided in the form of a semiconductor wafer or another type of semiconductor substrate.

As shown in FIG. 3B, the integrated circuit devices 118 may be formed in and/or on the device layer 112 of the semiconductor die 104. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer of the device layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer of the device layer 112 with one or more types of dopants (e.g., p-type dopants, n-type dopants).

As shown FIG. 3C, a first portion of the dielectric layer(s) 126 of the interconnect layer 114 may be formed on the first side of the semiconductor layer of the device layer 112. A deposition tool may be used to deposit the first portion of the dielectric layer(s) 126 using a CVD technique, an ALD technique, a PVD technique, an oxidation technique, and/or another type of deposition technique. In some implementations, a planarization tool is used to planarize the first portion of the dielectric layer(s) 126.

As further shown in FIG. 3C, a first subset of the conductive structures 128 of the interconnect layer 114 may be formed in the first portion of the dielectric layer(s) 126. The first subset of the conductive structures 128 may be formed in recesses in the first portion of the dielectric layer(s) 126. In some implementations, a pattern in a photoresist layer is used to etch the first portion of the dielectric layer(s) 126 to form the recesses. In these implementations, a deposition tool may be used to form the photoresist layer on the first portion of the dielectric layer(s) 126. An exposure tool may be used to expose the photoresist layer to a radiation source to pattern the photoresist layer. A developer tool may be used to develop and remove portions of the photoresist layer to expose the pattern. An etch tool may be used to etch the first portion of the dielectric layer(s) 126 based on the pattern to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the first subset of the conductive structures 128 using a CVD technique, an ALD technique, a PVD technique, an electroplating technique, and/or another type of deposition technique. In some implementations, a planarization tool is used to planarize the first subset of the conductive structures 128 after the first subset of the conductive structures 128 is deposited.

As shown in FIG. 3D, a recess 302 is formed through the first portion of the dielectric layer(s) 126 and into a portion of the semiconductor layer of the device layer 112. The first portion of the dielectric layer(s) 126 and the semiconductor layer of the device layer 112 may be etched to form the recess 302. The direction of the etch (e.g., from the first portion of the dielectric layer(s) 126 to the semiconductor layer of the device layer 112) results in the recess 302 having a tapered cross-sectional profile, similar to the elongated conductive structure 140, as described in connection with FIG. 1B.

The recess 302 includes sidewalls having a dielectric portion (corresponding to the first portion of the dielectric layer(s) 126) and a semiconductor portion (correspond to the semiconductor layer of the device layer 112). The bottom surface of the recess 302 includes a semiconductor surface corresponding the semiconductor layer of the device layer 112.

In some implementations, a pattern in a photoresist layer is used to etch the first portion of the dielectric layer(s) 126 to form the recess 302. In these implementations, a deposition tool may be used to form the photoresist layer on the first portion of the dielectric layer(s) 126. An exposure tool may be used to expose the photoresist layer to a radiation source to pattern the photoresist layer. A developer tool may be used to develop and remove portions of the photoresist layer to expose the pattern. An etch tool may be used to etch the first portion of the dielectric layer(s) 126 based on the pattern to form the recess 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 302 based on a pattern.

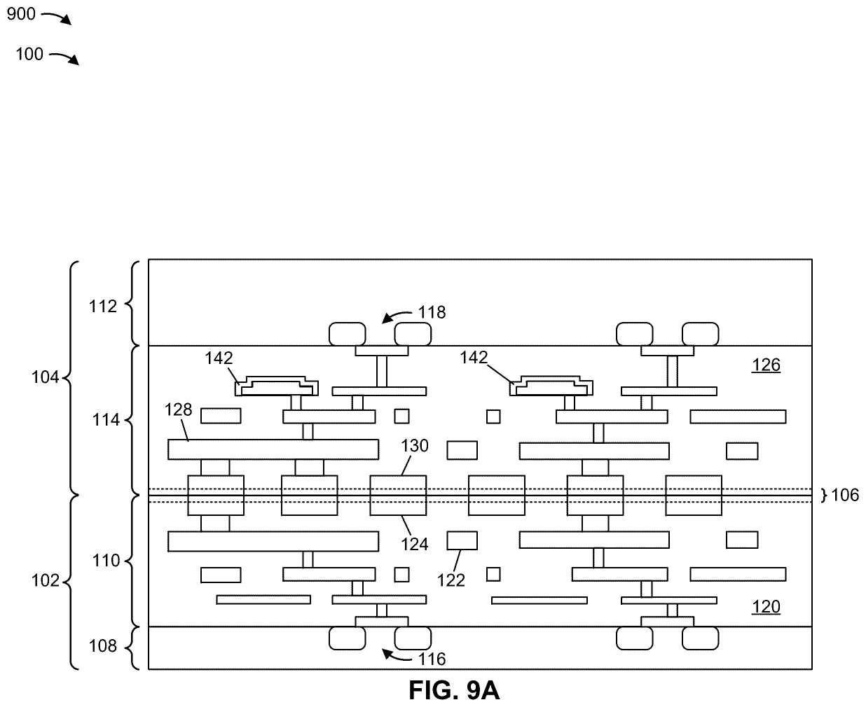

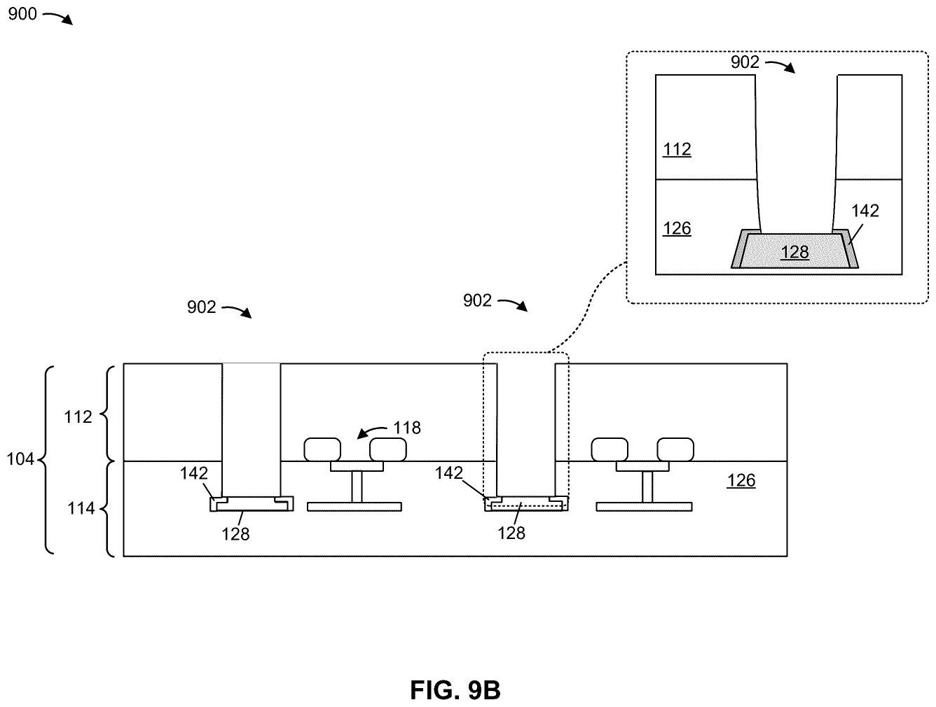

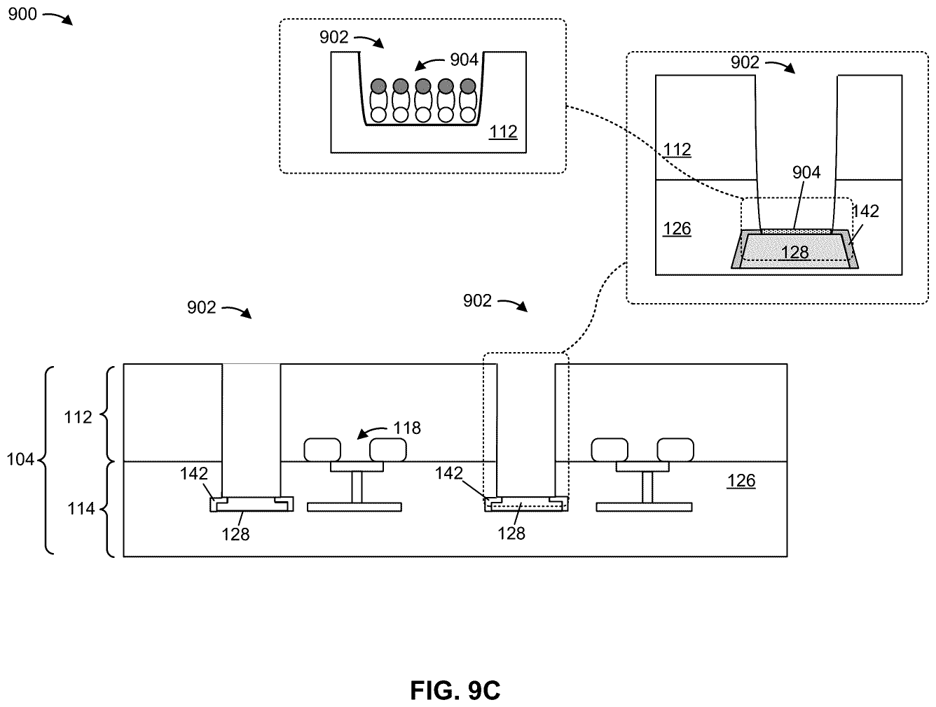

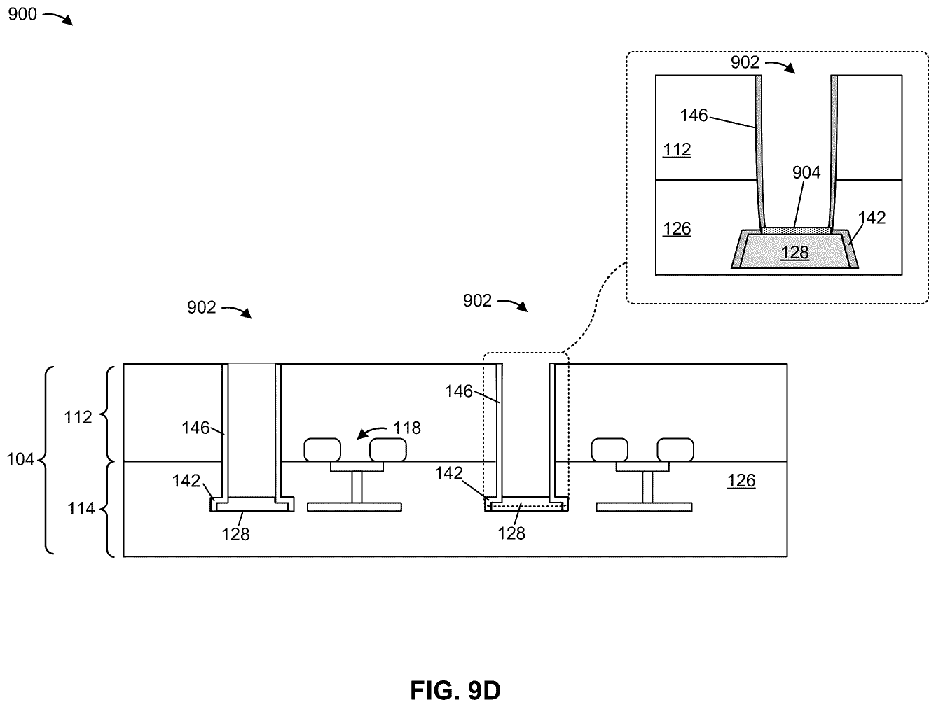

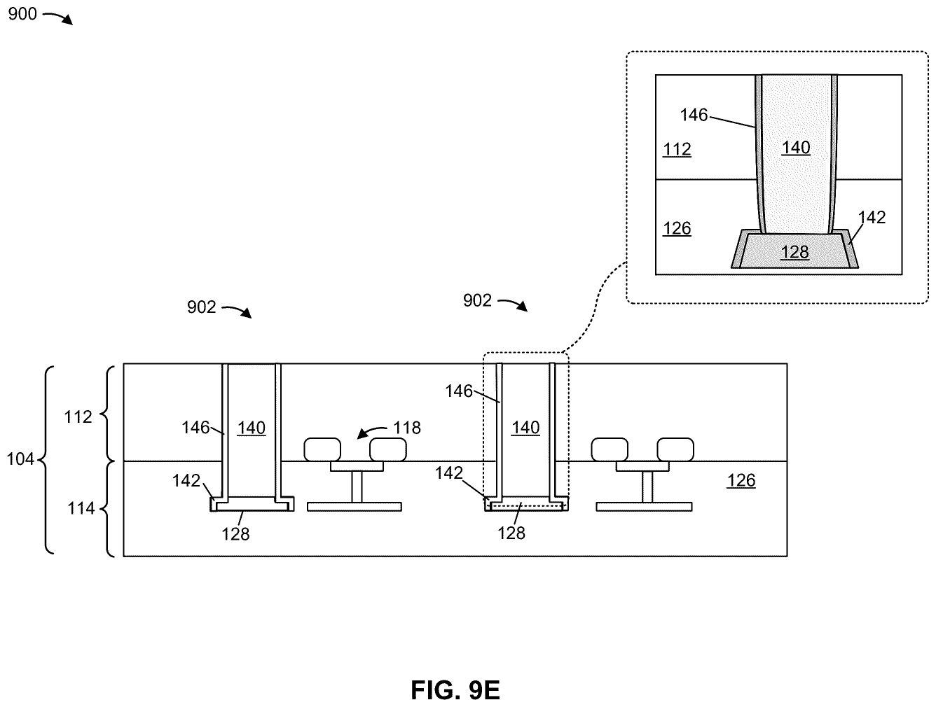

As shown in FIG. 3E, a barrier layer 146 is formed on the sidewalls and on the bottom surface of the recess 302. Alternatively, a blocking layer may be used to prevent the barrier layer 146 from being formed on the bottom surface of the recess 302 such that the barrier layer 146 is formed only on the sidewalls of the recess 302, as described in connection with FIGS. 9A-9D. The barrier layer 146 may be conformally deposited using an ALD technique, a CVD technique, and/or another suitable conformal deposition technique.

As shown in FIG. 3F, an elongated conductive structure 140 is formed on the barrier layer 146 in the recess 302. Thus, the barrier layer 146 is between the sidewalls of the elongated conductive structure 140 and the dielectric portion of the sidewalls of the recess 302, is between the sidewalls of the elongated conductive structure 140 and the semiconductor portion of the sidewalls of the recess 302, and is between the bottom end of the elongated conductive structure 140 and the bottom surface of the recess 302. A deposition tool may be used to deposit the conductive structure 136 using a CVD technique, an ALD technique, a PVD technique, an electroplating technique, and/or another type of deposition technique. In some implementations, a planarization tool is used to planarize the elongated conductive structure 140 after the elongated conductive structure 140 is deposited.

As shown in FIG. 3G, a second portion of the dielectric layer(s) 126 of the interconnect layer 114 may be formed on the first portion and on the top side of the elongated conductive structure 140. A deposition tool may be used to deposit the second portion of the dielectric layer(s) 126 using a CVD technique, an ALD technique, a PVD technique, an oxidation technique, and/or another type of deposition technique. In some implementations, a planarization tool is used to planarize the second portion of the dielectric layer(s) 126.

As shown in FIG. 3H, a recess 304 is formed through the second portion of the dielectric layer(s) 126 and to the top end of the elongated conductive structure 140. The recess 304 may be formed in preparation for forming a conductive structure 128 on the top side of the elongated conductive structure 140. In some implementations, additional recesses are formed in preparation for forming additional conductive structures 128 in the second portion of the dielectric layer(s) 126.

The recess 304 includes sidewalls and a bottom surface. The sidewalls and a portion of the bottom surface of the recess 304 correspond to the second portion of the dielectric layer(s) 126. Another portion of bottom surface of the recess 304 corresponds to exposed portions of the barrier layer 146. Yet another portion of the bottom surface of the recess 304 corresponds to the top side of the elongated conductive structure 140.

In some implementations, a pattern in a photoresist layer is used to etch the second portion of the dielectric layer(s) 126 to form the recess 304. In these implementations, a deposition tool may be used to form the photoresist layer on the second portion of the dielectric layer(s) 126. An exposure tool may be used to expose the photoresist layer to a radiation source to pattern the photoresist layer. A developer tool may be used to develop and remove portions of the photoresist layer to expose the pattern. An etch tool may be used to etch the second portion of the dielectric layer(s) 126 based on the pattern to form the recess 304. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 304 based on a pattern.

As shown in FIG. 3I, a blocking layer 306 is formed on the top side of the elongated conductive structure 140 in the recess 304. In particular, the blocking layer 306 is formed on the top side of the elongated conductive structure 140 and not on the sidewalls and the portions of the bottom surface of the recess 304 that correspond to the dielectric layer(s) 126 and/or that correspond to the exposed portions of the barrier layer 146.

The blocking layer 306 may include one or more materials 308 that selectively adsorb onto the material of the top side of the elongated conductive structure 140, and do not adsorb (or minimally adsorb) onto the material of the dielectric sidewalls and dielectric portions of the bottom surface of the recess 304, including the exposed portions of the barrier layer 146. For example, the material of the elongated conductive structure 140 may include copper (Cu), and the material 308 of the blocking layer 306 may include benzotriazole (BTA), toyltriazole (TTA), and/or another material that selectively bonds to the top end of the elongated conductive structure 140 and does not bond with the dielectric materials in the recess 304.

To form the blocking layer 306, a surface treatment operation may be performed to treat the surface of the top end of the elongated conductive structure 140. The surface treatment operation may include providing the material 308 of the blocking layer 306 into the recess 304 such that the surface of the top end of the elongated conductive structure 140 is soaked for a time duration to form the blocking layer 306 on the surface of the top end of the elongated conductive structure 140. While the surface of the top end of the elongated conductive structure 140 soaks in the material 308 of the blocking layer 306, a material complex forms on the surface of the top end of the elongated conductive structure 140. The material complex includes a copper-BTA complex, a copper-TTA complex, and/or another type of material complex that acts as a copper corrosion inhibitor. The material complex forms as electron donor sites of the material 308 of the blocking layer 306 that covalently bond with electron acceptor sites of the material of the elongated conductive structure 140. The electron donor sites include lone pair electrons of nitrogen atoms in the material 308 of the blocking layer 306, and those lone pair electrons bond with the electron acceptor sites in the metal material of the elongated conductive structure 140.

As shown in FIG. 3J, while the blocking layer 306 is on the top side of the elongated conductive structure 140, the barrier layer 142 is formed on the dielectric sidewalls and dielectric bottom portions of the recess 304, including on the exposed portions of the barrier layer 146. Thus, the barrier layer 142 connects with the barrier layer 146 to provide a continuous barrier layer against material diffusion. The blocking layer 306 inhibits or prevents growth of the barrier layer 142 on the top side of the elongated conductive structure 140. In particular, the material 308 of the blocking layer 306 exhibits hydrophobic blocking of absorption of the material of the barrier layer 142 into the surface of the top side of the elongated conductive structure 140.

As an example, the material of the elongated conductive structure 140 may include copper (Cu), and the material of the barrier layer 142 may include tantalum nitride (TaN). The material 308 of the blocking layer 306 acts a copper corrosion inhibitor and prevents, minimizes, and/or reduces the absorption of tantalum nitride precursors (such as pentakis(dimethylamino)tantalum (PDMAT)) into the copper surface of the top side of the elongated conductive structure 140.

As shown in FIG. 3K, the blocking layer 306 is subsequently removed from the top side of the elongated conductive structure 140 after the barrier layer 142 is formed in the recess 304. The blocking layer 306 may be removed by etching, plasma treatment (e.g., plasma ashing or plasma etching), and/or another material removal technique. For example, a plasma treatment operation may be performed to remove the blocking layer 306 from the top side of the elongated conductive structure 140 using an ammonia-based plasma, an oxygen-based plasma, a hydrogen-based plasma, or a plasma including another type of ions. The plasma may bombard the blocking layer 306 with ammonia ions, oxygen ions, or another type of ions to sputter etch the blocking layer 306 off of the top side of the elongated conductive structure 140. An anneal may be performed to vaporize the removed material 308 of the blocking layer 306, and the vaporized material may be vacuumed from a processing chamber in which the semiconductor die 104 is located.

As shown in FIG. 3L, a conductive structure 128 may be formed in the recess 304. The conductive structure 128 is formed such that the conductive structure 128 lands directly on, and is in physical contact with, the top side of the elongated conductive structure 140. Thus, the interface 148 between a portion of the bottom surface of the conductive structure 128 and the elongated conductive structure 140 is a metal-to-metal (e.g., a copper-to-copper) direct physical connection. The other portions of the bottom surface of the conductive structure 128 and the sidewalls of the conductive structure 128 are in physical contact with the barrier layer 142. A deposition tool may be used to deposit the conductive structure 128 using a CVD technique, an ALD technique, a PVD technique, an electroplating technique, and/or another type of deposition technique. In some implementations, a planarization tool is used to planarize the conductive structure 128 after the conductive structure 128 is deposited.

As shown in FIG. 3M, additional portions of the dielectric layer(s) 126 and additional conductive structures 128 may be formed in the interconnect layer 114 above the elongated conductive structure(s) 140. Moreover, the bonding pads 130 may be formed on the topmost conductive structures 128. The additional portions of the dielectric layer(s) 126, the additional conductive structures 128, and the bonding pads 130 may be formed using techniques similar to those described in connection with FIGS. 2C-2E.

As indicated above, FIGS. 3A-3M are provided as an example. Other examples may differ from what is described with regard to FIGS. 3A-3M.

FIGS. 4A-4J are diagrams of an example implementation 400 of forming a semiconductor die package described herein. For example, the example implementation 400 may include an example of forming a semiconductor die package 100. In some implementations, one or more of the operations described in connection with the example implementation 400 may be performed to form another semiconductor die package described herein, such as a semiconductor die package 500 illustrated in FIG. 5A and/or a semiconductor die package 600 illustrated in FIG. 6, among other examples. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

As shown in FIGS. 4A and 4B, a bonding operation is performed to bond the semiconductor die 102 and the semiconductor die 104 at the bonding interface 106 such that the semiconductor die 102 and the semiconductor die 104 are vertically arranged or stacked in the semiconductor die package 100. The semiconductor die 102 and the semiconductor die 104 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection of the bonding pads 124 of the semiconductor die 102 with the bonding pads 130 of the semiconductor die 104, and through a direct physical connection of one or more of the dielectric layers 120 of the semiconductor die 102 with one or more dielectric layers 126 of the semiconductor die 104.

As shown in FIG. 4C, the second side of the semiconductor layer of the device layer 112 may be thinned to expose the bottom ends of the elongated conductive structures 140 through the second side of the semiconductor layer of the device layer 112. A planarization tool or a grinding tool may be used to perform a planarization operation or a grinding operation (e.g., a silicon grinding operation) to remove material from the second side of the semiconductor layer of the device layer 112. The planarization operation or grinding operation also removes the barrier layer 146 from the bottom ends of the elongated conductive structures 140.

As shown FIG. 4D, a portion of the dielectric layer(s) 134 of the interconnect layer 132 may be formed on the second side of the semiconductor layer of the device layer 112. The portion of the dielectric layer(s) 134 is also formed on the exposed bottom ends of the elongated conductive structures 140. A deposition tool may be used to deposit the portion of the dielectric layer(s) 134 using a CVD technique, an ALD technique, a PVD technique, an oxidation technique, and/or another type of deposition technique. In some implementations, a planarization tool is used to planarize the portion of the dielectric layer(s) 134.

As shown in FIG. 4E, a recess 402 is formed in and through the portion of the dielectric layer(s) 134. The recess 402 is formed over the bottom end of an elongated conductive structure 140 such that the bottom end of the elongated conductive structure 140 is exposed through the recess 402. The recess 402 includes dielectric sidewalls corresponding to the portion of the dielectric layer(s) 134. The recess 402 also includes a bottom surface, a portion of which corresponds to the semiconductor layer of the device layer 112 (or alternatively to the portion of the dielectric layer(s) 134), another portion of which corresponds to exposed portions of the barrier layer 146, and another portion of which corresponds to the bottom end of the elongated conductive structure 140.

In some implementations, a pattern in a photoresist layer is used to etch the portion of the dielectric layer(s) 134 to form the recess 402. In these implementations, a deposition tool may be used to form the photoresist layer on the portion of the dielectric layer(s) 134. An exposure tool may be used to expose the photoresist layer to a radiation source to pattern the photoresist layer. A developer tool may be used to develop and remove portions of the photoresist layer to expose the pattern. An etch tool may be used to etch the portion of the dielectric layer(s) 134 based on the pattern to form the recess 402. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 402 based on a pattern.

As shown in FIG. 4F, a blocking layer 404 is formed on the bottom end of the elongated conductive structure 140 in the recess 402 using similar techniques as described in connection with FIG. 3I for the blocking layer 306. In particular, the blocking layer 404 is formed on the bottom end of the elongated conductive structure 140 and not on the dielectric sidewalls and semiconductor portions (or dielectric portions) of the bottom surface of the recess 402. Moreover, the material 406 of the blocking layer 404 inhibits growth of the blocking layer 404 on the exposed portions of the barrier layer 146.

As shown in FIG. 4G, while the blocking layer 404 is on the bottom end of the elongated conductive structure 140, the barrier layer 144 is formed on the dielectric sidewalls of the recess 402, and formed on the semiconductor portions and the dielectric portions of the bottom surface of the recess 402. Thus, the barrier layer 144 connects with the barrier layer 146 to provide a continuous barrier layer against material diffusion. The blocking layer 404 inhibits or blocks growth of the barrier layer 144 on the bottom end of the elongated conductive structure 140 in a similar manner as described in connection with FIG. 3J.

As shown in FIG. 4H, the blocking layer 404 is subsequently removed from the bottom end of the elongated conductive structure 140 after the barrier layer 144 is formed in the recess 402. The blocking layer 404 may be removed in a similar manner as described in connection with FIG. 3K.

As shown in FIG. 4I, the conductive structure 136 may be formed in the recess 402. The conductive structure 136 is formed such that the conductive structure 136 lands directly on, and is in physical contact with, the bottom end of the elongated conductive structure 140. Thus, the interface 150 between a portion of the bottom surface of the conductive structure 136 and the elongated conductive structure 140 is a metal-to-metal (e.g., a copper-to-copper) direct physical connection. The other portions of the bottom surface of the conductive structure 136 and the sidewalls of the conductive structure 136 are in physical contact with the barrier layer 144. A deposition tool may be used to deposit the conductive structure 136 using a CVD technique, an ALD technique, a PVD technique, an electroplating technique, and/or another type of deposition technique. In some implementations, a planarization tool is used to planarize the conductive structure 136 after the conductive structure 136 is deposited.

As shown in FIG. 4J, additional portions of the dielectric layer(s) 134 and additional conductive structures 136 may be formed in the interconnect layer 132. Moreover, the connection structures 138 may be formed on the topmost conductive structures 136. The additional portions of the dielectric layer(s) 134, the additional conductive structures 136, and the connection structures 138 may be formed using techniques similar to those used for forming the interconnect layers 110 and 114.

As indicated above, FIGS. 4A-4J are provided as an example. Other examples may differ from what is described with regard to FIGS. 4A-4J.

FIGS. 5A and 5B are diagrams of an example semiconductor die package 500 described herein. FIG. 5A illustrates a cross-section view of the semiconductor die package 500. As shown in FIG. 5A, the semiconductor die package 500 includes a similar combination and arrangement of structures and layers as the semiconductor die package 100. For example, the semiconductor die package 500 includes a semiconductor die 502 and a semiconductor die 504 bonded at a bonding interface, similar to the semiconductor dies 102 and 104 of the semiconductor die package 100.

Moreover, the semiconductor dies 502 and 504 include a similar combination and arrangement of layers and structures as the semiconductor dies 102 and 104, respectively. For example, the semiconductor die 502 includes a device layer 508, an interconnect layer 510, integrated circuit devices 516 in the device layer 508, one or more dielectric layers 520 and a plurality of conductive structures 522 in the interconnect layer 510, and bonding pads 524 in the interconnect layer 510. As another example, the semiconductor die 504 includes a device layer 512, an interconnect layer 514 on a first side of the device layer 512, integrated circuit devices 518 in the device layer 512, one or more dielectric layers 526 and a plurality of conductive structures 528 in the interconnect layer 514, and bonding pads 530 in the interconnect layer 514. Moreover, an interconnect layer 532 is included on a second side of the device layer 512 opposing the first side, and the interconnect layer 532 includes one or more dielectric layers 534, a plurality of conductive structures 536 in the one or more dielectric layers 534, and connection structures 538 connected to the conductive structures 536. One or more elongated conductive structures 540 extend between the interconnect layer 514 and the interconnect layer 532 through the semiconductor layer of the device layer 512. The elongated conductive structures 540 are connected at opposing ends to conductive structures 528 in the interconnect layer 514 and conductive structures 536 in the interconnect layer 532. Barrier layers 542, 544, and 546 are included on sidewalls of the conductive structures 528, on sidewalls of the conductive structures 536, and on sidewalls of the elongated conductive structures 540, respectively. Barrier layers 542, 544, and 546 are formed in a manner described in connection with FIGS. 3A-3M and 4A-4J such that the elongated conductive structures 540 are in direct physical contact (e.g., metal-to-metal contact or copper-to-copper contact) with the associated conductive structures 528 and 536.

However, the connection structures 538 differ from the connection structures 138 in that the connection structures 538 include micro bumps, controlled collapse chip connection (C4) bumps, ball grid array (BGA) connections, and/or another type of connection structure that enables the semiconductor die package 500 to be mounted to a substrate (e.g., an interposer, a device package substrate) through solder connections. Under bump metallization (UBM) layers 548 may be included between the connection structures 538 and the underlying conductive structures 536 to facilitate adhesion between the connection structures 538 and the underlying conductive structures 536.

Moreover, the elongated conductive structures 540 differ from the elongated conductive structures 140 in that the elongated conductive structures 540 extend further (or deeper) into the interconnect layer 514 than the elongated conductive structures 140 extend into the interconnect layer 114. For example, the elongated conductive structures 540 may be connected with bonding vias near the bonding interface 506, or connected with one or more conductive structures 528 that are connected with the bonding vias. Thus, the elongated conductive structures 540 are taller (or longer in the vertical direction in the semiconductor die package 500) than the elongated conductive structures 140.

As shown in FIG. 5B, the semiconductor die 504 may have one or more example dimensions. An example dimension D6 includes a cross-sectional width of an elongated conductive structure 540 at an interface 550 between the elongated conductive structure 540 and an associated conductive structure 536. Another example dimension D7 includes a cross-sectional width of the elongated conductive structure 540 at an interface 552 between the elongated conductive structure 540 and an associated conductive structure 528. Another example dimension D8 includes a thickness or vertical direction length of the elongated conductive structure 540.

Another example dimension D9 includes an angle between a sidewall of the elongated conductive structure 540 and a bottom surface of the associated conductive structure 536. Another example dimension D10 includes an angle between a sidewall of the elongated conductive structure 540 and a bottom surface of the associated conductive structure 528.

In some implementations, the dimension D6 is included in a range of approximately 1.6 microns and approximately 2.0 microns, the dimension D7 is included in a range of approximately 1.8 microns to approximately 2.2 microns, and the dimension D8 is included in a range of approximately 10 microns to approximately 40 microns for a system on integrated chip (SoIC) type semiconductor die package 500. However, other values and ranges for these dimensions are within the scope of the present disclosure. In some implementations, a ratio of the dimension D7 to the dimension D6 is included in a range of approximately 1.1:1 to approximately 1.13:1, a ratio of the dimension D8 to the dimension D6 is included in a range of approximately 6.25:1 to approximately 20:1, and/or a ratio of the dimension D8 to the dimension D7 is included in a range of approximately 5.5:1 to approximately 18:1 for an SoIC type semiconductor die package 500. However, other values and ranges for these ratios are within the scope of the present disclosure.

In some implementations, the dimension D6 is included in a range of approximately 2.6 microns to approximately 3.0 microns, the dimension D7 is included in a range of approximately 2.8 microns to approximately 3.2 microns, and the dimension D8 is included in a range of approximately 10 microns to approximately 40 microns for an SoIC type semiconductor die package 500. However, other values and ranges for these dimensions are within the scope of the present disclosure. In some implementations, a ratio of the dimension D7 to the dimension D6 is included in a range of approximately 1.06:1 to approximately 1.08:1, a ratio of the dimension D8 to the dimension D6 is included in a range of approximately 4:1 to approximately 13.33:1, and/or a ratio of the dimension D8 to the dimension D7 is included in a range of approximately 3.5:1 to approximately 12.5:1 for an SoIC type semiconductor die package 500. However, other values and ranges for these ratios are within the scope of the present disclosure.

In some implementations, the dimension D6 is included in a range of approximately 4.1 microns and approximately 4.5 microns, the dimension D7 is included in a range of approximately 4.3 microns to approximately 4.7 microns, and the dimension D8 is included in a range of approximately 40 microns to approximately 65 microns for another type of three-dimensionally stacked semiconductor die package 500. However, other values and ranges for these dimensions are within the scope of the present disclosure. In some implementations, a ratio of the dimension D7 to the dimension D6 is included in a range of approximately 1.04:1 to approximately 1.05:1, a ratio of the dimension D8 to the dimension D6 is included in a range of approximately 9.75:1 to approximately 14.5:1, and/or a ratio of the dimension D8 to the dimension D7 is included in a range of approximately 9.25:1 to approximately 13:1 for another type of three-dimensionally stacked semiconductor die package 500. However, other values and ranges for these ratios are within the scope of the present disclosure.

In some implementations, the dimension D9 is included in a range of approximately 60 degrees to approximately 90 degrees. However, other values for the range are within the scope of the present disclosure. In some implementations, the dimension D10 is included in a range of approximately 90 degrees to approximately 120 degrees. However, other values for the range are within the scope of the present disclosure. In some implementations, a difference between the dimension D9 and the dimension D10 is included in a range of approximately 0 degrees to approximately 10 degrees. However, other values for the range are within the scope of the present disclosure.

As indicated above, FIGS. 5A and 5B are provided as an example. Other examples may differ from what is described with regard to FIGS. 5A and 5B.

FIG. 6 is a diagram of an example semiconductor die package 600 described herein. FIG. 6 illustrates a cross-section view of the semiconductor die package 600. As shown in FIG. 6, the semiconductor die package 600 includes a similar combination and arrangement of structures and layers as the semiconductor die 104 in the semiconductor die package 100. In other words, the semiconductor die package 600 may include a single packaged semiconductor die. For example, the semiconductor die package 600 includes a device layer 602 (corresponding to the device layer 112), an interconnect layer 604 (corresponding to the interconnect layer 114) on a first side of the device layer 602, and an interconnect layer 606 (corresponding to the interconnect layer 132) on a second side of the device layer 602 opposing the first side.

In some implementations, the interconnect layer 604 is configured to provide routing of signals between integrated circuit devices 608 (corresponding to integrated circuit devices 118) in the device layer 602 and/or between the integrated circuit devices 608 and external integrated circuit devices, and the interconnect layer 606 is configured to provide power delivery to the integrated circuit devices 608 in the device layer 602. In some implementations, the interconnect layer 606 is configured to provide routing of signals between integrated circuit devices 608 in the device layer 602 and/or between the integrated circuit devices 608 and external integrated circuit devices, and the interconnect layer 604 is configured to provide power delivery to the integrated circuit devices 608 in the device layer 602. In some implementations, the interconnect layers 604 and 606 are configured to provide a mix of signal routing of and power delivery in the semiconductor die package 600.

The interconnect layer 604 includes one or more dielectric layers 610 (corresponding to dielectric layer(s) 126) and a plurality of conductive structures 612 (corresponding to conductive structures 128) in the one or more dielectric layers 610. The interconnect layer 606 includes one or more dielectric layers 614 (corresponding to dielectric layer(s) 134), a plurality of conductive structures 616 (corresponding to conductive structures 136) in the one or more dielectric layers 614, and connection structures 618 (corresponding to connection structures 138) connected to the conductive structures 616.

As further shown in FIG. 6, the semiconductor die package 600 includes one or more elongated conductive structures 620 (corresponding to elongated conductive structure(s) 140) that extend between the interconnect layers 604 and 606 through a semiconductor layer of the device layer 602. The elongated conductive structures 620 are connected at opposing ends to conductive structures 612 in the interconnect layer 604 and conductive structures 616 in the interconnect layer 606. Barrier layers 622, 624, and 626 (respectively corresponding to barrier layers 142, 144, and 146) are included on sidewalls of the conductive structures 612, on sidewalls of the conductive structures 616, and on sidewalls of the elongated conductive structures 620, respectively. The barrier layers 622, 624, and 626 are formed in a manner described in connection with FIGS. 3A-3M and 4A-4J such that the elongated conductive structures 620 are in direct physical contact (e.g., metal-to-metal contact or copper-to-copper contact) with the associated conductive structures 612 and 616.

As indicated above, FIG. 6 is provided as an example. Other examples may differ from what is described with regard to FIG. 6.

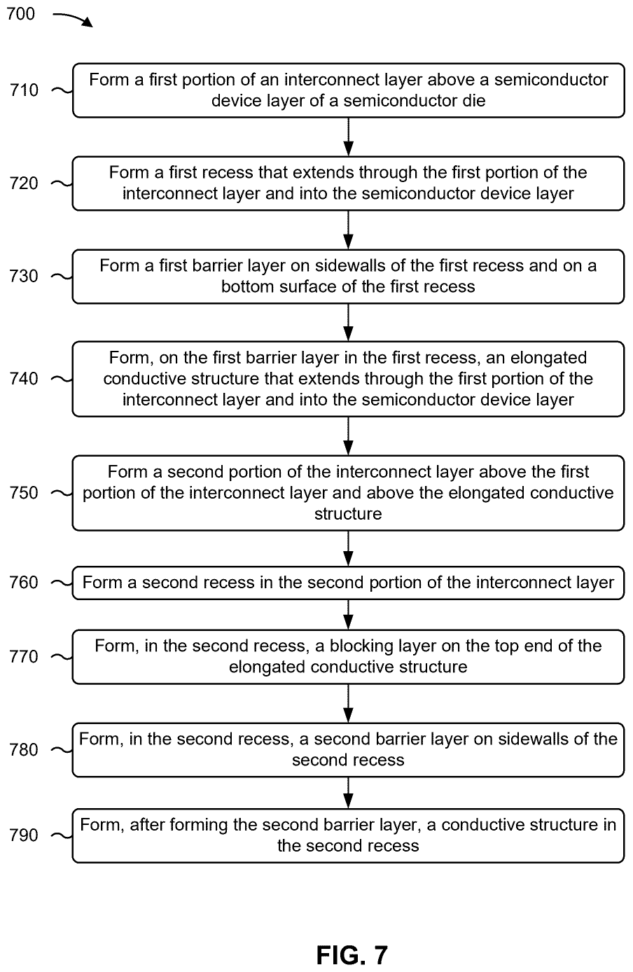

FIG. 7 is a flowchart of an example process 700 associated with forming a semiconductor die described herein. In some implementations, one or more process blocks of FIG. 7 are performed using one or more semiconductor processing tools.

As shown in FIG. 7, process 700 may include forming a first portion of an interconnect layer above a semiconductor device layer of a semiconductor die (block 710). For example, one or more semiconductor processing tools may be used to form a first portion of an interconnect layer (e.g., an interconnect layer 114, 514, and/or 604) above a semiconductor device layer (e.g., a device layer 112, 512, and/or 602) of a semiconductor die (e.g., a semiconductor die 104, a semiconductor die 504, a semiconductor die in a semiconductor die package 600), as described herein.

As further shown in FIG. 7, process 700 may include forming a first recess that extends through the first portion of the interconnect layer and into the semiconductor device layer (block 720). For example, one or more semiconductor processing tools may be used to form a first recess (e.g., a recess 302) that extends through the first portion of the interconnect layer and into the semiconductor device layer, as described herein.

As further shown in FIG. 7, process 700 may include forming a first barrier layer on sidewalls of the first recess and on a bottom surface of the first recess (block 730). For example, one or more semiconductor processing tools may be used to form a first barrier layer (e.g., a barrier layer 146, 546, and/or 626) on sidewalls of the first recess and on a bottom surface of the first recess, as described herein.

As further shown in FIG. 7, process 700 may include forming, on the first barrier layer in the first recess, an elongated conductive structure that extends through the first portion of the interconnect layer and into the semiconductor device layer (block 740). For example, one or more semiconductor processing tools may be used to form, on the first barrier layer in the first recess, an elongated conductive structure (e.g., an elongated conductive structure 140, 540, and/or 620) that extends through the first portion of the interconnect layer and into the semiconductor device layer, as described herein.

As further shown in FIG. 7, process 700 may include forming a second portion of the interconnect layer above the first portion of the interconnect layer and above the elongated conductive structure (block 750). For example, one or more semiconductor processing tools may be used to form a second portion of the interconnect layer above the first portion of the interconnect layer and above the elongated conductive structure, as described herein.

As further shown in FIG. 7, process 700 may include forming a second recess in the second portion of the interconnect layer (block 760). For example, one or more semiconductor processing tools may be used to form a second recess (e.g., a recess 304) in the second portion of the interconnect layer, as described herein. In some implementations, a top end of the elongated conductive structure is exposed through the second recess.

As further shown in FIG. 7, process 700 may include forming, in the second recess, a blocking layer on the top end of the elongated conductive structure (block 770). For example, one or more semiconductor processing tools may be used to form, in the second recess, a blocking layer (e.g., a blocking layer 306) on the top end of the elongated conductive structure, as described herein.

As further shown in FIG. 7, process 700 may include forming, in the second recess, a second barrier layer on sidewalls of the second recess (block 780). For example, one or more semiconductor processing tools may be used to form, in the second recess, a second barrier layer (e.g., a barrier layer 142, 542, and/or 622) on sidewalls of the second recess, as described herein. In some implementations, the blocking layer inhibits growth of the second barrier layer on the top end of the elongated conductive structure.

As further shown in FIG. 7, process 700 may include forming, after forming the second barrier layer, a conductive structure in the second recess (block 790). For example, one or more semiconductor processing tools may be used to form, after forming the second barrier layer, a conductive structure (e.g., a conductive structure 128, 528, and/or 612) in the second recess, as described herein. In some implementations, the conductive structure lands directly on the top end of the elongated conductive structure.

Process 700 may include additional implementations, such as any single implementation or any combination of implementations described below and/or in connection with one or more other processes described elsewhere herein.

In a first implementation, the blocking layer bonds to the top end of the elongated conductive structure and does not bond with the sidewalls of the second recess.

In a second implementation, alone or in combination with the first implementation, a material (e.g., a material 308) of the blocking layer includes electron donor sites that covalently bond with electron acceptor sites of a material of the elongated conductive structure.

In a third implementation, alone or in combination with one or more of the first and second implementations, a material of the elongated conductive structure includes copper (Cu), and a material (e.g., a material 308) of the blocking layer comprises at least one of benzotriazole (BTA) or toyltriazole (TTA).

In a fourth implementation, alone or in combination with one or more of the first through third implementations, a material precursor of the second barrier layer includes pentakis(dimethylamino)tantalum (PDMAT), and a material of the barrier layer blocks the PDMAT from being deposited onto the top end of the elongated conductive structure.

In a fifth implementation, alone or in combination with one or more of the first through fourth implementations, a first portion of a bottom of the second recess corresponds to the top end of the elongated conductive structure, a second portion of the second recess corresponds to a dielectric layer (e.g., a dielectric layer 126, 526, and/or 610) of the interconnect layer, and the blocking layer bonds with the first portion of the bottom of the second recess and not with the second portion of the bottom of the second recess.

In a sixth implementation, alone or in combination with one or more of the first through fourth implementations, the process 700 includes removing the blocking layer after forming the second barrier layer and prior to forming the conductive structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

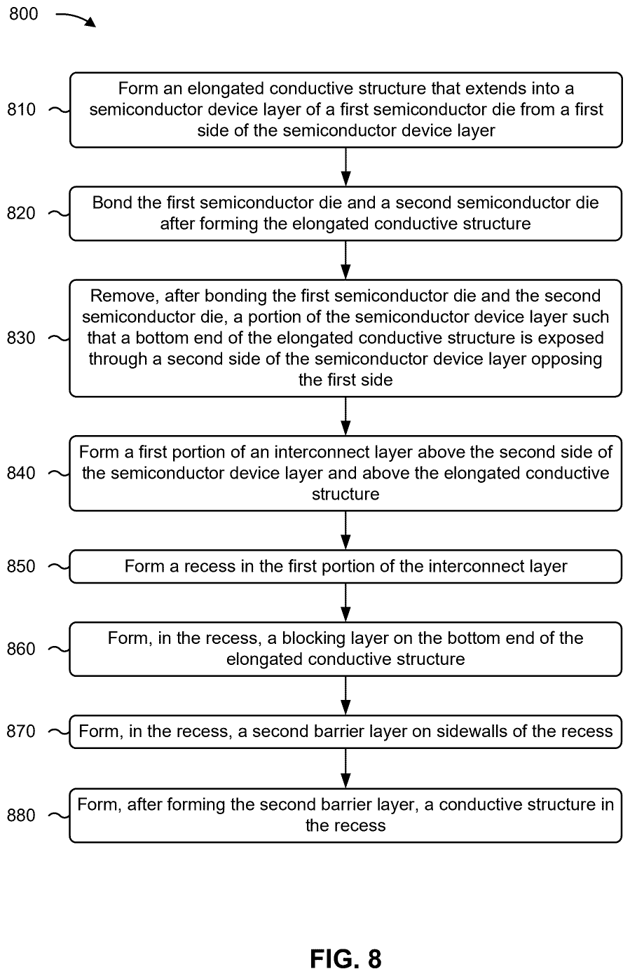

FIG. 8 is a flowchart of an example process 800 associated with forming a semiconductor die package described herein. In some implementations, one or more process blocks of FIG. 8 are performed using one or more semiconductor processing tools.

As shown in FIG. 8, process 800 may include forming an elongated conductive structure that extends into a semiconductor device layer of a first semiconductor die from a first side of the semiconductor device layer (block 810). For example, one or more semiconductor processing tools may be used to form an elongated conductive structure (e.g., an elongated conductive structure 140 and/or 540) that extends into a semiconductor device layer (e.g., a device layer 112 and/or 512) of a first semiconductor die (e.g., a semiconductor die 104 and/or 504) from a first side of the semiconductor device layer, as described herein. In some implementations, a first barrier layer (e.g., a barrier layer 146 and/or 546) is included between the semiconductor device layer and sidewalls and a bottom end of the elongated conductive structure.

As further shown in FIG. 8, process 800 may include bonding the first semiconductor die and a second semiconductor die after forming the elongated conductive structure (block 820). For example, one or more semiconductor processing tools may be used to bond the first semiconductor die and a second semiconductor die (e.g., a semiconductor die 102 and/or 502) after forming the elongated conductive structure, as described herein.

As further shown in FIG. 8, process 800 may include removing, after bonding the first semiconductor die and the second semiconductor die, a portion of the semiconductor device layer such that the bottom end of the elongated conductive structure is exposed through a second side of the semiconductor device layer opposing the first side (block 830). For example, one or more semiconductor processing tools may be used to remove, after bonding the first semiconductor die and the second semiconductor die, a portion of the semiconductor device layer such that the bottom end of the elongated conductive structure is exposed through a second side of the semiconductor device layer opposing the first side, as described herein.

As further shown in FIG. 8, process 800 may include forming a first portion of an interconnect layer above the second side of the semiconductor device layer and above the elongated conductive structure (block 840). For example, one or more semiconductor processing tools may be used to form a first portion of an interconnect layer (e.g., an interconnect layer 132 and/or 532) above the second side of the semiconductor device layer and above the elongated conductive structure, as described herein.

As further shown in FIG. 8, process 800 may include forming a recess in the first portion of the interconnect layer (block 850). For example, one or more semiconductor processing tools may be used to form a recess (e.g., a recess 402) in the first portion of the interconnect layer, as described herein. In some implementations, the bottom end of the elongated conductive structure is exposed through the recess.

As further shown in FIG. 8, process 800 may include forming, in the recess, a blocking layer on the bottom end of the elongated conductive structure (block 860). For example, one or more semiconductor processing tools may be used to form, in the recess, a blocking layer (e.g., a blocking layer 404) on the bottom end of the elongated conductive structure, as described herein.

As further shown in FIG. 8, process 800 may include forming, in the recess, a second barrier layer on sidewalls of the recess (block 870). For example, one or more semiconductor processing tools may be used to form, in the recess, a second barrier layer (e.g., a barrier layer 144 and/or 544) on sidewalls of the recess, as described herein. In some implementations, the blocking layer inhibits growth of the second barrier layer on the bottom end of the elongated conductive structure.

As further shown in FIG. 8, process 800 may include forming, after forming the second barrier layer, a conductive structure in the recess (block 880). For example, one or more semiconductor processing tools may be used to form, after forming the second barrier layer, a conductive structure (e.g., a conductive structures 136 and/or 536) in the recess, as described herein. In some implementations, the conductive structure is in direct contact with the bottom end of the elongated conductive structure.

Process 800 may include additional implementations, such as any single implementation or any combination of implementations described below and/or in connection with one or more other processes described elsewhere herein.

In a first implementation, a material (e.g., a material 406) of the blocking layer includes a copper corrosion inhibitor.

In a second implementation, alone or in combination with the first implementation, forming the blocking layer includes providing a material (e.g., a material 406) of the blocking layer onto the bottom end of the elongated conductive structure in the recess, and soaking the bottom end of the elongated conductive structure in the material of the blocking layer to form the blocking layer on the bottom end of the elongated conductive structure.

In a third implementation, alone or in combination with one or more of the first and second implementations, forming the blocking layer includes providing a material (e.g., a material 406) of the blocking layer onto the bottom end of the elongated conductive structure in the recess such that nitrogen lone pair electrons in the material of the blocking layer bond with a metal material of the elongated conductive structure.

In a fourth implementation, alone or in combination with one or more of the first through third implementations, a first portion of a bottom of the recess corresponds to the bottom end of the elongated conductive structure, a second portion of the recess corresponds to a portion of the semiconductor device layer, and the blocking layer bonds with the first portion of the bottom of the recess and not with the second portion of the bottom of the recess.

In a fifth implementation, alone or in combination with one or more of the first through fourth implementations, the blocking layer blocks precursors of a material of the second barrier layer from being absorbed by the bottom end of the elongated conductive structure.

In a sixth implementation, alone or in combination with one or more of the first through fourth implementations, the process 800 includes removing the blocking layer after forming the second barrier layer and prior to forming the conductive structure.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

FIGS. 9A-9E are diagrams of an example implementation 900 of forming a semiconductor die described herein. In some implementations, the example implementation 900 includes an example process for forming an elongated conductive structure 140 through the device layer 112 of the semiconductor die 104 after bonding the semiconductor die 102 and the semiconductor die 104. In other words, the example implementation 900 is an alternative to the elongated conductive structure 140 formation techniques illustrated and described in connection with FIGS. 3A-3M and 4A-4J. In some implementations, one or more of the operations described in connection with the example implementation 900 may be performed to form a portion of a semiconductor die package described herein, such as a semiconductor die package 600 illustrated in FIG. 6. In some implementations, one or more semiconductor processing tools may be used to perform one or more of the operations described in connection with the example implementation 900, such as a deposition tool, an exposure tool, a developer tool, an etch tool, a planarization tool, a plating tool, and/or another type of semiconductor processing tool.

As shown in FIG. 9A, one or more of the operations in the example implementation 300 and/or 400 may be performed to form the semiconductor dies 102 and 104, and to bond the semiconductor dies 102 and 104 at the bonding interface 106.

As shown in FIG. 9B, recesses 902 are formed from the back side of the device layer 112 (e.g., the side opposing the side on which the interconnect layer 114 was formed), through the device layer 112, and into the interconnect layer 114 to underling conductive structures 128. Thus, the recesses 902 for the elongated conductive structures 140 are formed after the semiconductor dies 102 and 104 are bonded.

As shown in FIGS. 9C and 9D, a barrier layer 146 is formed on the sidewalls of the recess 902 in a similar manner as described in connection with FIG. 3E. However, instead of the barrier layer 146 being formed on the bottom surface of the recess 902, a blocking layer 904 is formed on the bottom surface of the recess 902 as shown in FIG. 9C, and the blocking layer 904 inhibits growth of the barrier layer 146 on the bottom surface of the recess 902 (e.g., on the conductive structure 128 at the bottom of the recess 902) such that the barrier layer 146 is formed only on the sidewalls of the recess 902 as shown in FIG. 9D. The blocking layer 904 may be formed in a similar manner as the blocking layer 306 described in connection with FIG. 3I.

As shown in FIG. 9E, the blocking layer 904 may be subsequently removed from the bottom surface of the recess 902 after formation of the barrier layer 146. The blocking layer 904 may be removed in a similar manner as the blocking layer 306 described in connection with FIG. 3K.

As further shown in FIG. 9E an elongated conductive structure 140 is formed in the recess 902 such that the barrier layer 146 is between the sidewalls of the conductive structure 140 and the dielectric layers 126 of the interconnect layer 114, and between the sidewalls of the conductive structure 140 and the device layer 112. The elongated conductive structure 140 may be formed in a similar manner as described in connection with FIG. 3F, except that the elongated conductive structure 140 is formed from the back side of the device layer 112 after formation of the interconnect layer 114 instead of from the front side of the device layer 112 prior to formation of the interconnect layer 114. The elongated conductive structure 140 extends fully through the device layer 112 and into the interconnect layer 114 to the underlying conductive structure.

Moreover, since the blocking layer 904 prevented formation of the barrier layer 146 on the bottom surface of the recess 902 (e.g., on the surface of the underlying conductive structure 128 at the bottom of the recess 902), the elongated conductive structure 140 lands directly on the surface of the underlying conductive structure 128 at the bottom of the recess 902. Thus, a direct copper-to-copper bond is formed between the elongated conductive structure 140 and the underlying conductive structure 128.

As indicated above, FIGS. 9A-9E are provided as an example. Other examples may differ from what is described with regard to FIGS. 9A-9E.

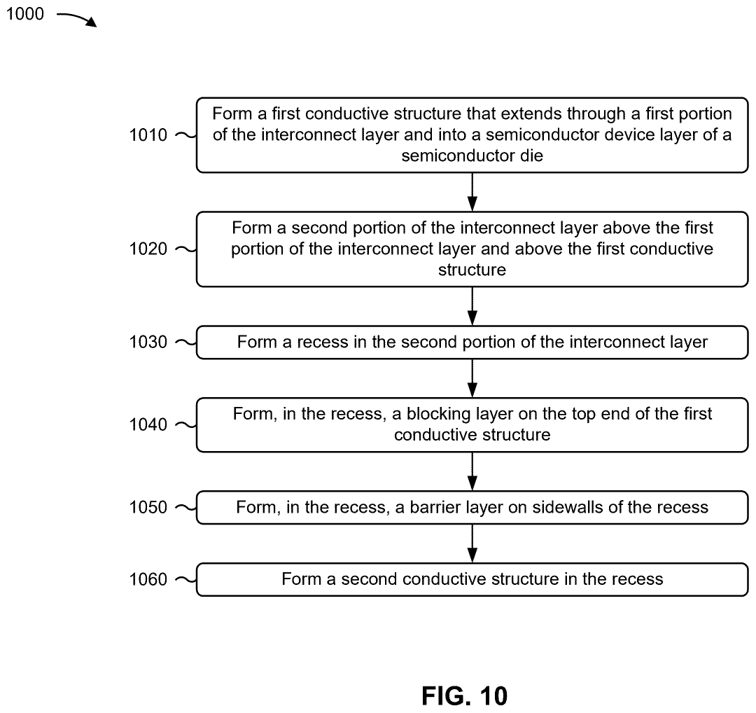

FIG. 10 is a flowchart of an example process 1000 associated with forming a semiconductor die package described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 10, process 1000 may include forming a first conductive structure that extends through a first portion of the interconnect layer and into a semiconductor device layer of a semiconductor die (block 1010). For example, one or more semiconductor processing tools may be used to form a first conductive structure (e.g., an elongated conductive structure 140) that extends through a first portion of the interconnect layer (e.g., an interconnect layer 114) and into a semiconductor device layer (e.g., a device layer 112) of a semiconductor die (e.g., a semiconductor die 104), as described herein.

As further shown in FIG. 10, process 1000 may include forming a second portion of the interconnect layer above the first portion of the interconnect layer and above the first conductive structure (block 1020). For example, one or more semiconductor processing tools may be used to form a second portion of the interconnect layer above the first portion of the interconnect layer and above the first conductive structure, as described herein.

As further shown in FIG. 10, process 1000 may include forming a recess in the second portion of the interconnect layer (block 1030). For example, one or more semiconductor processing tools may be used to form a recess (e.g., a recess 304) in the second portion of the interconnect layer, as described herein. In some implementations, a top end of the first conductive structure is exposed through the recess.

As further shown in FIG. 10, process 1000 may include forming, in the recess, a blocking layer on the top end of the first conductive structure (block 1040). For example, one or more semiconductor processing tools may be used to form, in the recess, a blocking layer (e.g., a blocking layer 306) on the top end of the first conductive structure, as described herein.

As further shown in FIG. 10, process 1000 may include forming, in the recess, a barrier layer on sidewalls of the second recess (block 1050). For example, one or more semiconductor processing tools may be used to form, in the recess, a barrier layer (e.g., a barrier layer 142) on sidewalls of the recess, as described herein.

As further shown in FIG. 10, process 1000 may include forming a second conductive structure in the recess (block 1060). For example, one or more semiconductor processing tools may be used to form a second conductive structure (e.g., a conductive structure 128) in the recess, as described herein.

Process 1000 may include additional implementations, such as any single implementation or any combination of implementations described below and/or in connection with one or more other processes described elsewhere herein.

In a first implementation, the blocking layer inhibits growth of the barrier layer on the top end of the first conductive structure, and wherein the blocking layer bonds to the top end of the first conductive structure and does not bond with the sidewalls of the recess.

In a second implementation, alone or in combination with the first implementation, a material of the blocking layer includes electron donor sites that covalently bond with electron acceptor sites of a material of the first conductive structure.

In a third implementation, alone or in combination with one or more of the first and second implementations, a material of the first conductive structure comprises copper (Cu), and wherein a material of the blocking layer comprises at least one of benzotriazole (BTA) or toyltriazole (TTA).

In a fourth implementation, alone or in combination with one or more of the first through third implementations, a material precursor of the barrier layer includes pentakis(dimethylamino)tantalum (PDMAT), and wherein a material of the barrier layer blocks the PDMAT from being deposited onto the top end of the first conductive structure.

In a fifth implementation, alone or in combination with one or more of the first through fourth implementations, a first portion of a bottom of the recess corresponds to the top end of the first conductive structure, a second portion of the recess corresponds to a dielectric layer of the interconnect layer, and the blocking layer bonds with the first portion of the bottom of the recess and not with the second portion of the bottom of the second recess.

In a sixth implementation, alone or in combination with one or more of the first through fifth implementations, process 1000 includes removing the blocking layer after forming the second barrier layer and prior to forming the conductive structure, where the second conductive structure lands directly on the top end of the first conductive structure.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

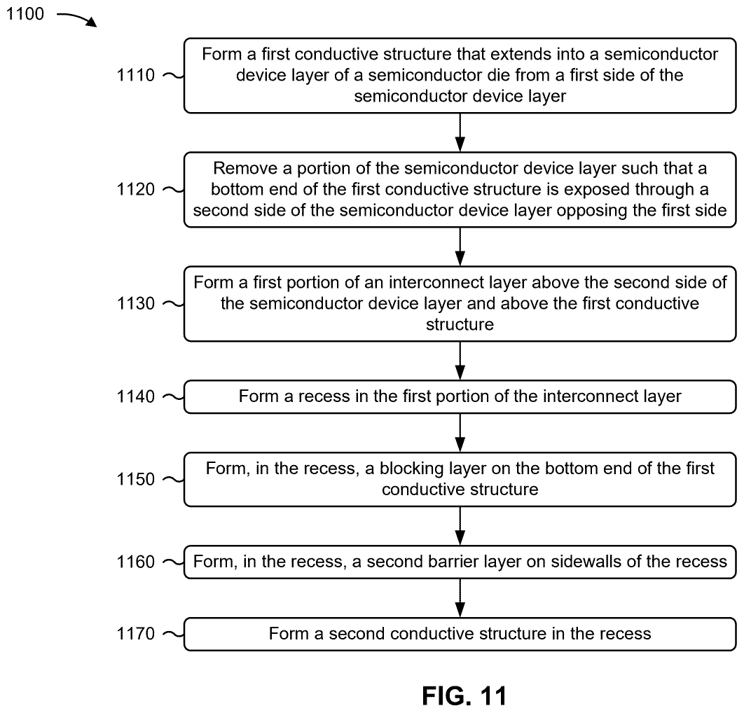

FIG. 11 is a flowchart of an example process 1100 associated with forming a semiconductor die package described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a first conductive structure that extends into a semiconductor device layer of a semiconductor die from a first side of the semiconductor device layer (block 1110). For example, one or more semiconductor processing tools may be used to form a first conductive structure (e.g., an elongated conductive structure 140) that extends into a semiconductor device layer (e.g., a device layer 112) of a semiconductor die (e.g., a semiconductor die 104) from a first side (e.g., a front side) of the semiconductor device layer, as described herein.

As further shown in FIG. 11, process 1100 may include removing a portion of the semiconductor device layer such that a bottom end of the first conductive structure is exposed through a second side of the semiconductor device layer opposing the first side (block 1120). For example, one or more semiconductor processing tools may be used to remove a portion of the semiconductor device layer such that a bottom end of the first conductive structure is exposed through a second side (e.g., a back side) of the semiconductor device layer opposing the first side, as described herein.

As further shown in FIG. 11, process 1100 may include forming a first portion of an interconnect layer above the second side of the semiconductor device layer and above the first conductive structure (block 1130). For example, one or more semiconductor processing tools may be used to form a first portion of an interconnect layer (e.g., an interconnect layer 132) above the second side of the semiconductor device layer and above the first conductive structure, as described herein.

As further shown in FIG. 11, process 1100 may include forming a recess in the first portion of the interconnect layer (block 1140). For example, one or more semiconductor processing tools may be used to form a recess (e.g., a recess 402) in the first portion of the interconnect layer, as described herein. In some implementations, the bottom end of the first conductive structure is exposed through the recess.

As further shown in FIG. 11, process 1100 may include forming, in the recess, a blocking layer on the bottom end of the first conductive structure (block 1150). For example, one or more semiconductor processing tools may be used to form, in the recess, a blocking layer (e.g., a blocking layer 404) on the bottom end of the first conductive structure, as described herein.

As further shown in FIG. 11, process 1100 may include forming, in the recess, a second barrier layer on sidewalls of the recess (block 1160). For example, one or more semiconductor processing tools may be used to form, in the recess, a second barrier layer (e.g., a barrier layer 144) on sidewalls of the recess, as described herein.

As further shown in FIG. 11, process 1100 may include forming a second conductive structure in the recess (block 1170). For example, one or more semiconductor processing tools may be used to form a second conductive structure (e.g., a conductive structure 136) in the recess, as described herein.

Process 1100 may include additional implementations, such as any single implementation or any combination of implementations described below and/or in connection with one or more other processes described elsewhere herein.

In a first implementation, a material of the blocking layer includes a copper corrosion inhibitor, and the blocking layer inhibits growth of the barrier layer on the bottom end of the first conductive structure.

In a second implementation, alone or in combination with the first implementation, forming the blocking layer includes providing a material of the blocking layer onto the bottom end of the first conductive structure in the recess, and soaking the bottom end of the first conductive structure in the material of the blocking layer to form the blocking layer on the bottom end of the first conductive structure.

In a third implementation, alone or in combination with one or more of the first and second implementations, forming the blocking layer includes providing a material of the blocking layer onto the bottom end of the first conductive structure in the recess such that nitrogen lone pair electrons in the material of the blocking layer bond with a metal material of the first conductive structure.

In a fourth implementation, alone or in combination with one or more of the first through third implementations, a first portion of a bottom of the recess corresponds to the bottom end of the first conductive structure, a second portion of the recess corresponds to a portion of the semiconductor device layer, and the blocking layer bonds with the first portion of the bottom of the recess and not with the second portion of the bottom of the recess.

In a fifth implementation, alone or in combination with one or more of the first through fourth implementations, the blocking layer blocks precursors of a material of the second barrier layer from being absorbed by the bottom end of the first conductive structure.

In a sixth implementation, alone or in combination with one or more of the first through fifth implementations, process 1100 includes removing the blocking layer after forming the second barrier layer and prior to forming the conductive structure, where the second conductive structure lands directly on the bottom end of the first conductive structure.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, an elongated conductive structure is included through a device layer of a semiconductor die included in a semiconductor die package. The elongated conductive structure connects to metallization layers in the interconnect layers on opposing sides of the device layer. To achieve a low contact resistance between the elongated conductive structure and the metallization layers, blocking material is used to inhibit growth of barrier layers on the elongated conductive structure during formation of the barrier layers for the metallization layers. This enables the metallization layers to land directly on the elongated conductive structure, as opposed to the barrier layers being between the elongated conductive structure and the metallization layers. In this way, metal-to-metal connections may be achieved between the conductive structure and the metallization layers, which enables a low contact resistance to be achieved between the conductive structure and the metallization layers while enabling barrier layers to be formed to provide diffusion protection for the metallization layers. This enables low power consumption and increased signal propagation speeds to be achieved in the semiconductor die package.

As described in greater detail above, some implementations described herein provide a method. The method includes forming a first portion of an interconnect layer above a semiconductor device layer of a semiconductor die. The method includes forming a first recess that extends through the first portion of the interconnect layer and into the semiconductor device layer. The method includes forming a first barrier layer on sidewalls of the first recess and on a bottom surface of the first recess. The method includes forming, on the first barrier layer in the first recess, an elongated conductive structure that extends through the first portion of the interconnect layer and into the semiconductor device layer. The method includes forming a second portion of the interconnect layer above the first portion of the interconnect layer and above the elongated conductive structure. The method includes forming a second recess in the second portion of the interconnect layer, where a top end of the elongated conductive structure is exposed through the second recess. The method includes forming, in the second recess, a blocking layer on the top end of the elongated conductive structure. The method includes forming, in the second recess, a second barrier layer on sidewalls of the second recess, where the blocking layer inhibits growth of the second barrier layer on the top end of the elongated conductive structure. The method includes forming, after forming the second barrier layer, a conductive structure in the second recess, where the conductive structure lands directly on the top end of the elongated conductive structure.

As described in greater detail above, some implementations described herein provide a method. The method includes forming an elongated conductive structure that extends into a semiconductor device layer of a first semiconductor die from a first side of the semiconductor device layer, where a first barrier layer is included between the semiconductor device layer and sidewalls and a bottom end of the elongated conductive structure. The method includes bonding the first semiconductor die and a second semiconductor die after forming the elongated conductive structure. The method includes removing, after bonding the first semiconductor die and the second semiconductor die, a portion of the semiconductor device layer such that the bottom end of the elongated conductive structure is exposed through a second side of the semiconductor device layer opposing the first side. The method includes forming a first portion of an interconnect layer above the second side of the semiconductor device layer and above the elongated conductive structure. The method includes forming a recess in the first portion of the interconnect layer, where the bottom end of the elongated conductive structure is exposed through the recess. The method includes forming, in the recess, a blocking layer on the bottom end of the elongated conductive structure. The method includes forming, in the recess, a second barrier layer on sidewalls of the recess, where the blocking layer inhibits growth of the second barrier layer on the bottom end of the elongated conductive structure. The method includes forming, after forming the second barrier layer, a conductive structure in the recess, where the conductive structure is in direct contact with the bottom end of the elongated conductive structure.

As described in greater detail above, some implementations described herein provide a semiconductor die package. The semiconductor die package includes a semiconductor device layer. The semiconductor die package includes one or more semiconductor device. The semiconductor die package includes a first interconnect layer vertically adjacent to a first side of the semiconductor device layer. The semiconductor die package includes a second interconnect layer vertically adjacent to a second side of the semiconductor device layer opposing the first side. The semiconductor die package includes a metal pillar extending through the semiconductor device layer. The semiconductor die package includes a first metal pad in the first interconnect layer, where the first metal pad is in direct physical contact with a first end of the metal pillar. The semiconductor die package includes a second metal pad in the first interconnect layer, where the second metal pad is in direct physical contact with a second end of the metal pillar opposing the first end.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first conductive structure that extends through a first portion of the interconnect layer and into a semiconductor device layer of a semiconductor die;
forming a second portion of the interconnect layer above the first portion of the interconnect layer and above the first conductive structure;
forming a recess in the second portion of the interconnect layer,
wherein a top end of the first conductive structure is exposed through the recess;
forming, in the recess, a blocking layer on the top end of the first conductive structure;
forming, in the recess, a barrier layer on sidewalls of the recess; and
forming a second conductive structure in the recess.

2. The method of claim 1, wherein the blocking layer inhibits growth of the barrier layer on the top end of the first conductive structure; and
wherein the blocking layer bonds to the top end of the first conductive structure and does not bond with the sidewalls of the recess.

3. The method of claim 2, wherein a material of the blocking layer comprises electron donor sites that covalently bond with electron acceptor sites of a material of the first conductive structure.

4. The method of claim 1, wherein a material of the first conductive structure comprises copper (Cu); and
wherein a material of the blocking layer comprises at least one of benzotriazole (BTA) or toyltriazole (TTA).

5. The method of claim 1, wherein a material precursor of the barrier layer comprises pentakis(dimethylamino)tantalum (PDMAT); and
wherein a material of the barrier layer blocks the PDMAT from being deposited onto the top end of the first conductive structure.

6. The method of claim 1, wherein a first portion of a bottom of the recess corresponds to the top end of the first conductive structure;
wherein a second portion of the recess corresponds to a dielectric layer of the interconnect layer; and
wherein the blocking layer bonds with the first portion of the bottom of the recess and not with the second portion of the bottom of the second recess.

7. The method of claim 1, further comprising:
removing the blocking layer after forming the second barrier layer and prior to forming the conductive structure,
wherein the second conductive structure lands directly on the top end of the first conductive structure.

8. A method, comprising:
forming a first conductive structure that extends into a semiconductor device layer of a semiconductor die from a first side of the semiconductor device layer;
removing a portion of the semiconductor device layer such that a bottom end of the first conductive structure is exposed through a second side of the semiconductor device layer opposing the first side;
forming a first portion of an interconnect layer above the second side of the semiconductor device layer and above the first conductive structure;
forming a recess in the first portion of the interconnect layer,
wherein the bottom end of the first conductive structure is exposed through the recess;
forming, in the recess, a blocking layer on the bottom end of the first conductive structure;
forming, in the recess, a second barrier layer on sidewalls of the recess; and
forming a second conductive structure in the recess.

9. The method of claim 8, wherein a material of the blocking layer comprises a copper corrosion inhibitor, and
wherein the blocking layer inhibits growth of the barrier layer on the bottom end of the first conductive structure.

10. The method of claim 8, wherein forming the blocking layer comprises providing a material of the blocking layer onto the bottom end of the first conductive structure in the recess; and
soaking the bottom end of the first conductive structure in the material of the blocking layer to form the blocking layer on the bottom end of the first conductive structure.

11. The method of claim 8, wherein forming the blocking layer comprises providing a material of the blocking layer onto the bottom end of the first conductive structure in the recess such that nitrogen lone pair electrons in the material of the blocking layer bond with a metal material of the first conductive structure.

12. The method of claim 8, wherein a first portion of a bottom of the recess corresponds to the bottom end of the first conductive structure;
wherein a second portion of the recess corresponds to a portion of the semiconductor device layer; and
wherein the blocking layer bonds with the first portion of the bottom of the recess and not with the second portion of the bottom of the recess.

13. The method of claim 8, wherein the blocking layer blocks precursors of a material of the second barrier layer from being absorbed by the bottom end of the first conductive structure.

14. The method of claim 8, further comprising:
removing the blocking layer after forming the second barrier layer and prior to forming the conductive structure,
wherein the second conductive structure lands directly on the bottom end of the first conductive structure.

15. A semiconductor die package, comprising:
a semiconductor device layer;
one or more integrated circuit devices;
a first interconnect layer vertically adjacent to a first side of the semiconductor device layer;
a second interconnect layer vertically adjacent to a second side of the semiconductor device layer opposing the first side;
a metal pillar extending through the semiconductor device layer;
a first metal pad in the first interconnect layer,
wherein the first metal pad is in direct physical contact with a first end of the metal pillar; and
a second metal pad in the second interconnect layer,
wherein the second metal pad is in direct physical contact with a second end of the metal pillar opposing the first end.

16. The semiconductor die package of claim 15, wherein a cross-sectional width of the metal pillar decreases from the first end of the metal pillar to the second end of the metal pillar.

17. The semiconductor die package of claim 15, further comprising:
a first barrier layer between sidewalls of the metal pillar and the semiconductor device layer, and between the sidewalls of the metal pillar and a dielectric layer of the first interconnect layer; and
a second barrier layer between sidewalls of the first metal pad and the dielectric layer of the first interconnect layer.

18. The semiconductor die package of claim 17, further comprising:
a third barrier layer between sidewalls of the second metal pad and a dielectric layer of the second interconnect layer.

19. The semiconductor die package of claim 18, wherein a portion of the second barrier layer is in direct physical contact with a first portion of the first barrier layer; and
wherein a portion of the third barrier layer is in direct physical contact with a second portion of the first barrier layer.

20. The semiconductor die package of claim 15, wherein a cross-sectional width of the first end of the metal pillar is greater than a cross-sectional width of the second end of the metal pillar.
